(19) United States
(12) Patent Application Publication
(10) Pub. No.: US 2024/0407198 A1
(43) Pub. Date: Dec. 5, 2024

(54) DISPLAY DEVICE AND METHOD FOR MANUFACTURING THE SAME

(71) Applicant: Samsung Display Co., Ltd., Yongin-si (KR)

(72) Inventor: SANGHYUNG LIM, Yongin-si (KR)

(73) Assignee: Samsung Display Co., Ltd., Yongin-si (KR)

(21) Appl. No.: 18/644,562

(22) Filed: Apr. 24, 2024

(30) Foreign Application Priority Data
Jun. 5, 2023 (KR) 10-2023-0072391

(51) Int. Cl. H10K 59/122; H10K 59/12; H10K 59/131; H10K 59/35; H10K 59/38; H10K 59/80

(52) U.S. Cl. CPC H10K 59/122; H10K 59/1201; H10K 59/131; H10K 59/352; H10K 59/38; H10K 59/877

(57) ABSTRACT

A display device includes a display panel including a first to third pixel regions each emitting source light, a barrier rib disposed on the display panel and having first openings corresponding to each of the first pixel region, the second pixel region, and the third pixel region, a first light conversion pattern disposed in a first-first opening among the first openings corresponding to the first pixel region and converting the source light into first color light, a second light conversion pattern disposed in a first-second opening among the first openings corresponding to the second pixel region and converting the source light into second color light, and a division pattern, at least a portion of the division pattern being in contact with the barrier rib. The division pattern surrounds a corresponding one of the first pixel region, the second pixel region, and the third pixel region in a plan view.

### CROSS-REFERENCE TO RELATED APPLICATION(S)

This application claims priority to and benefits of Korean Patent Application No. 10-2023-0072391 under 35 U.S.C. § 119, filed on Jun. 5, 2023, in the Korean Intellectual Property Office (KIPO), the entire contents of which are incorporated herein by reference.

### BACKGROUND

### 1. Technical Field

The disclosure herein relates to a display device including a light conversion pattern, and a method for manufacturing the display device.

### 2. Description of the Related Art

A display panel includes a transmissive display panel that selectively transmits source light generated from a light source, and an emissive display panel that generates source light from a display panel itself. The display panel may include different types of light control patterns according to pixels to generate color images. The light control patterns may transmit only source light having a wavelength range or may convert the color of the source light. Some light control patterns may also alter light characteristics without changing the color of the source light.

### SUMMARY

According to an embodiment of the disclosure, a display device may include a display panel including a first pixel region, a second pixel region, and a third pixel region each emitting source light, a barrier rib disposed on the display panel and having first openings corresponding to each of the first pixel region, the second pixel region, and the third pixel region, a first light conversion pattern disposed in a first-first opening among the first openings corresponding to the first pixel region and converting the source light into first color light, a second light conversion pattern disposed in a first-second opening among the first openings corresponding to the second pixel region and converting the source light into second color light, and a division pattern, at least a portion of the division pattern being in contact with the barrier rib. The division pattern may surround a corresponding one of the first pixel region, the second pixel region, and the third pixel region in a plan view.

In an embodiment, in the division pattern, a division opening overlapping a corresponding one of the first pixel region, the second pixel region, and the third pixel region in a plan view may be defined, and the display device may further include an organic pattern disposed in the division opening.

In an embodiment, in a plan view, an area of the division opening may be greater than an area of each of the first openings.

In an embodiment, the display device may further include a transmission pattern disposed in a first-third opening among the first openings corresponding to the third pixel region and transmitting the source light. The transmission pattern and the division pattern may include a same material.

In an embodiment, a thickness deviation of the transmission pattern corresponding to the third pixel region may be less than a thickness deviation of the first light conversion pattern corresponding to the first pixel region.

In an embodiment, the division pattern may include a base resin and scattering particles mixed with the base resin.

In an embodiment, the first pixel region may include a plurality of first pixel regions, the second pixel region may include a plurality of second pixel regions, and the third pixel region may include a plurality of third pixel regions. The display panel may include a first pixel row including the plurality of first pixel regions and the plurality of third pixel regions, which are alternately arranged in a first direction, and a second pixel row spaced apart from the first pixel row in a second direction intersecting the first direction, and including the plurality of second pixel regions arranged in the first direction.

In an embodiment, the first pixel row may include a first pixel region group including n first pixel regions, the second pixel row may include a second pixel region group including m second pixel regions, the division pattern may include a first division pattern surrounding the first pixel region group in a plan view and a second division pattern surrounding the second pixel region group in a plan view, and n and m may each independently be an integer greater than or equal to 2.

In an embodiment, in the first division pattern, a first division opening overlapping the first pixel region and the third pixel region included in the first pixel region group may be defined, in the second division pattern, a second division opening overlapping the second pixel region included in the second pixel region group may be defined, and the display device may further include a first organic pattern disposed in the first division opening, and a second organic pattern disposed in the second division opening.

In an embodiment, the first pixel region may include a plurality of first pixel regions, the second pixel region may include a plurality of second pixel regions, and the third pixel region may include a plurality of third pixel regions. The display panel may include a first pixel row including the plurality of first pixel regions arranged in the first direction, and a second pixel row spaced apart from the first pixel row in a second direction intersecting the first direction, and including the plurality of second pixel regions arranged in the first direction.

In an embodiment, the first pixel row may include a first pixel region group including n first pixel regions arranged in the first direction, the second pixel row may include a second pixel region group including m second pixel regions arranged in the first direction, the division pattern may surround each of the first pixel region group and the second pixel region group in a plan view, and n and m may each independently be an integer greater than or equal to 2.

In an embodiment, the display panel may further include a third pixel row spaced apart from the first pixel row and the second pixel row in the second direction and including the third pixel regions arranged in the first direction, the third pixel row may include a third pixel region group including z third pixel regions arranged in the first direction, the division pattern may surround the third pixel region group in a plan view, and z may be an integer greater than or equal to 2.

In an embodiment, the display device may further include a color filter layer disposed on the barrier rib. The color filter layer may include a first filter that transmits the first color light, a second filter that transmits the second color light, and a third color filter that transmits the source light.

In an embodiment, the display device may further include a base layer facing the display panel in a thickness direction of the display panel. The barrier rib may be disposed on a lower surface of the base layer.

In an embodiment of the disclosure, a display device may include a display panel including a first pixel region, a second pixel region, and a third pixel region each emitting source light, and a light conversion panel disposed to be spaced apart from the display panel in a thickness direction of the display panel. The light conversion panel may include a base layer, a barrier rib disposed on a lower surface of the base layer and having first openings corresponding to the first pixel region, the second pixel region, and the third pixel region, a first light conversion pattern disposed in a first-first opening among the first openings corresponding to the first pixel region and converting the source light into first color light, a second light conversion pattern disposed in a first-second opening among the first openings corresponding to the second pixel region and converting the source light into second color light, a transmission pattern disposed in a first-third opening among the first openings corresponding to the third pixel region and transmitting the source light, and a division pattern disposed between the display panel and the barrier rib. The transmission pattern and the division pattern may include a same material.

In an embodiment of the disclosure, a method for manufacturing a display device may include preparing a substrate on which a first pixel region and a second pixel region are defined, forming a barrier rib including first openings corresponding to each of the first pixel region and the second pixel region, forming a photoresist layer on the substrate and the barrier rib, patterning the photoresist layer to form a division pattern having division openings overlapping each of the first pixel region and the second pixel region in a plan view, and forming a light conversion pattern inside ones of the first openings corresponding to the first pixel region and the second pixel region.

In an embodiment, a third pixel region adjacent to the first pixel region and the second pixel region may be defined on the substrate, the forming of the division pattern may include patterning the photoresist layer, using a mask in which a transmission portion overlapping a portion of the barrier rib and a semi-transmission portion overlapping the third pixel region in a plan view are defined, and in the forming of the division pattern, a transmission pattern may be formed inside ones of the first openings corresponding to the third pixel region.

In an embodiment, a third pixel region adjacent to the first pixel region and the second pixel region may be defined on the substrate, and in the forming of the division pattern, a first division pattern surrounding the first pixel region and the third pixel region in a plan view, and a second division pattern surrounding the second pixel region in a plan view may be formed.

In an embodiment, the forming of the light conversion pattern may include providing a liquid quantum dot composition to the inside the ones of the first openings.

In an embodiment, the method may further include forming an organic pattern filling each of the division openings.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1A is a perspective view of a display device according to an embodiment of the disclosure;

FIG. 1B is a schematic cross-sectional view of a display device according to an embodiment of the disclosure;

FIG. 1C is a plan view of a display panel according to an embodiment of the disclosure;

FIG. 2 is a schematic diagram of an equivalent circuit of a pixel according to an embodiment of the disclosure;

FIG. 3A is an enlarged plan view of a display region according to an embodiment of the disclosure;

FIG. 3B is an enlarged plan view of a display region according to an embodiment of the disclosure, which corresponds to region AA shown in FIG. 3A;

FIG. 3C is a schematic cross-sectional view corresponding to I-I′ of FIG. 3A;

FIG. 3D is a schematic cross-sectional view corresponding to II-II′ of FIG. 3A;

FIG. 4A is an enlarged plan view of a display region according to another embodiment of the disclosure;

FIG. 4B is a schematic cross-sectional view corresponding to III-III′ of FIG. 4A;

FIG. 5A is an enlarged plan view of a display region according to another embodiment of the disclosure;

FIG. 5B is a schematic cross-sectional view corresponding to IV-IV′ of FIG. 5A;

FIG. 6A is a perspective view of a display device according to an embodiment of the disclosure;

FIG. 6B is a schematic cross-sectional view of a display device according to an embodiment of the disclosure;

FIG. 7 is a flowchart showing a method for manufacturing a display device according to an embodiment of the disclosure;

FIGS. 8A to 8F are schematic cross-sectional views schematically showing processes in a method for manufacturing a display device according to an embodiment; and

FIGS. 9A and 9B are schematic cross-sectional views schematically showing some of the processes in a method for manufacturing a display device according to another embodiment.

### DETAILED DESCRIPTION OF THE EMBODIMENTS

Hereinafter, embodiments of the disclosure will be described with reference to the drawings.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like numbers refer to like elements throughout. In addition, in the drawings, the thickness, the ratio, and the dimensions of elements are exaggerated for an effective description of technical contents. The term “and/or,” includes all combinations of one or more of which associated configurations may define.

Although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the teachings of the disclosure. The singular forms are intended to include the plural forms as well, unless the context clearly indicates otherwise.

In addition, terms such as “below,” “lower,” “above,” “upper,” and the like are used to describe the relationship of the configurations shown in the drawings. The terms are used as a relative concept and are described with reference to the direction indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined, all terms (including technical and scientific terms) used herein have the same meaning as commonly understood by one of ordinary skill in the art to which the disclosure belongs. In addition, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a display device according to an embodiment of the disclosure and a method for manufacturing a display device will be described with reference to the accompanying drawings.

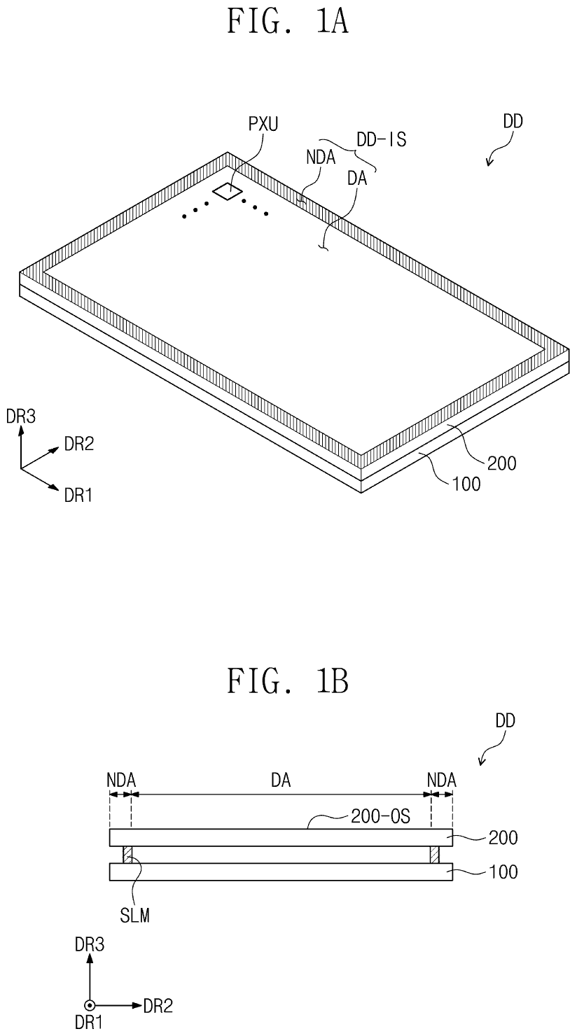

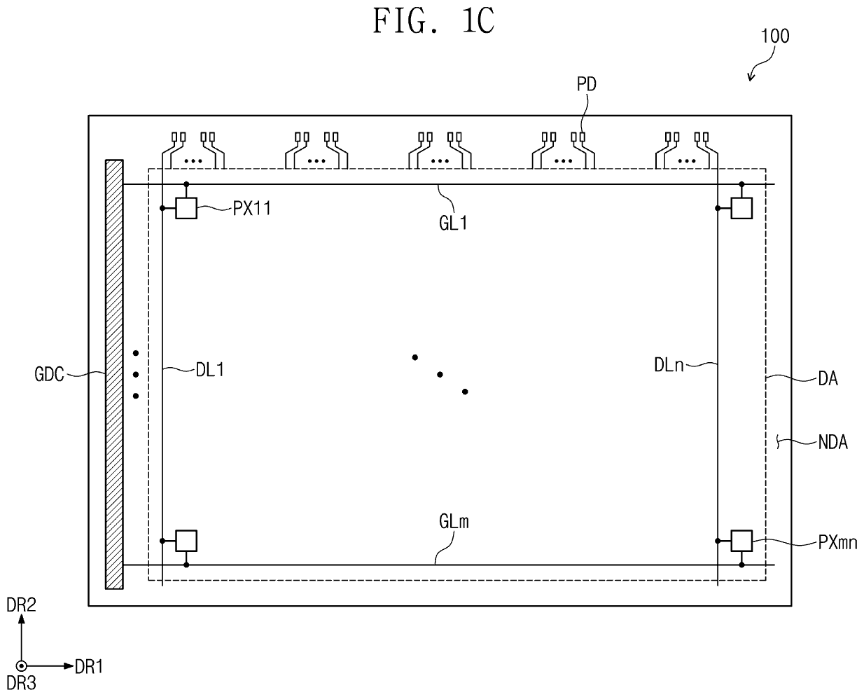

FIG. 1A is a perspective view of a display device DD according to an embodiment of the disclosure. FIG. 1B is a schematic cross-sectional view of a display device DD according to an embodiment of the disclosure. FIG. 1C is a plan view of a display panel 100 according to an embodiment of the disclosure.

Referring to FIG. 1A, the display device DD may display images through a display surface DD-IS. The display surface DD-IS may be parallel to a plane defined by a first direction DR1 and a second direction DR2. An upper surface of a member disposed on an uppermost side of the display device DD may be defined as the display surface DD-IS.

A normal direction of the display surface DD-IS, for example, a thickness direction of the display device DD, may be a third direction DR3. A front surface (or an upper surface) and a rear surface (or a lower surface) of respective layers or units which will be described below may be separated by the third direction DR3.

The display device DD may include a display region DA and a non-display region NDA. Unit pixels PXU may be disposed in the display region DA, and the unit pixels PXU may be not disposed in the non-display region NDA. The non-display region NDA may be defined along an edge of the display surface DD-IS. The non-display region NDA may surround the display region DA. In an embodiment of the disclosure, the non-display region NDA may be omitted or may be disposed only on a side of the display region DA. Although a flat display device DD is shown in FIG. 1A as an embodiment, the disclosure is not limited thereto, and the display device DD may have a curved shape, may be rollable, or may be slidable from a housing.

The unit pixels PXU shown in FIG. 1A may define rows and columns. The unit pixels PXU may be a minimum repeating unit, and the unit pixels PXU may include at least one pixel. The unit pixels PXU may include multiple pixels providing light of different colors.

Referring to FIG. 1B, the display device DD may include a display panel 100 (or a lower display substrate) and a light conversion panel 200 (or an upper display substrate) facing and spaced apart from the display panel 100. A cell gap may be formed between the display panel 100 and the light conversion panel 200. The cell gap may be maintained by a sealing member SLM bonding the display panel 100 and the light conversion panel 200 together. The scaling member SLM may include a binder resin and inorganic fillers mixed with the binder resin. The sealing member SLM may further include other additives. The additives may include an amine-based curing agent and a photo-initiator. The additives may further include a silane-based additive and an acryl-based additive. The sealing member SLM may include an inorganic material such as a frit.

Referring to FIG. 1B, the display panel 100 and the light conversion panel 200 may each have a display region DA and a non-display region NDA defined therein, just as the display device DD has the display region DA and the non-display region NDA. Hereinafter, the display region DA of the display device DD may indicate the display region DA of each of the display panel 100 and the light conversion panel 200, and the non-display region NDA of the display device DD may indicate the non-display region NDA of each of the display panel 100 and the light conversion panel 200.

FIG. 1C shows a planar arrangement relationship of signal lines GL1 to GLm and DL1 to DLn and pixels PX11 to PXmn. The signal lines GL1 to GLm and DL1 to DLn may include multiple gate lines GL1 to GLm and multiple data lines DL1 to DLn.

Each of the pixels PX11 to PXmn may be connected to a corresponding gate line among the gate lines GL1 to GLm and a corresponding data line among the data lines DL1 to DLn. Each of the pixels PX11 to PXmn may include a pixel driving circuit and a light emitting element. More types of signal lines may be provided in the display panel 100 according to configuration of the pixel driving circuit of the pixels PX11 to PXmn.

A gate driving circuit GDC may be integrated on the display panel 100 through an oxide silicon gate (OSG) driver circuit process or an amorphous silicon gate (ASG) driver circuit process. The gate driving circuit GDC connected to the gate lines GL1 to GLm may be disposed at a side of the non-display region NDA in the first direction DR1. Pads PD connected to ends of the data lines DL1 to DLn may be disposed on a side of the non-display region NDA in the second direction DR2.

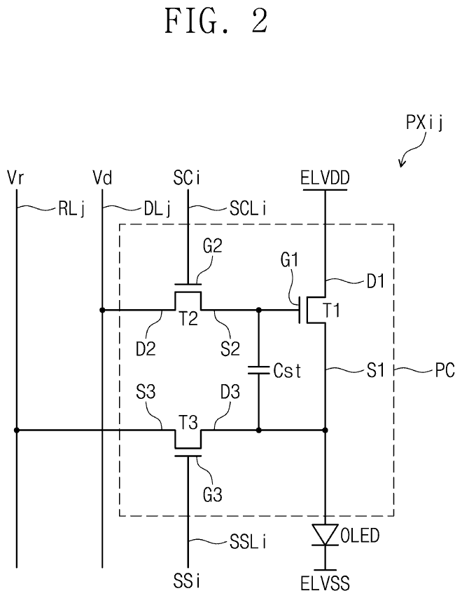

FIG. 2 is a schematic diagram of an equivalent circuit of a pixel PXij according to an embodiment of the disclosure.

FIG. 2 shows the pixel PXij connected to an i-th scan line SCLi, an i-th sensing line SSLi, a j-th data line DLj, and a j-th reference line RLj as an embodiment. The pixel PXij may include a pixel circuit PC and a light emitting element OLED connected to the pixel circuit PC. The pixel circuit PC may include multiple transistors T1 to T3 and a capacitor Cst. The transistors T1 to T3 may be formed through a low temperature polycrystalline silicon (LTPS) process or a low temperature polycrystalline oxide (LTPO) process. Hereinafter, the transistors T1 to T3 are described as N-type transistors, but the disclosure is not limited thereto, and at least one transistor may be provided as a P-type transistor.

In the embodiment, a pixel circuit PC including a first transistor T1 (or a driving transistor), a second transistor T2 (or a switch transistor), a third transistor T3 (or a sensing transistor), and a capacitor Cst is shown as an embodiment, but the pixel circuit PC is not limited thereto. The pixel circuit PC may include an additional transistor or an additional capacitor.

The light emitting element OLED may be an organic light emitting element or an inorganic light emitting element, which includes an anode (a first electrode) and a cathode (a second electrode). The anode of the light emitting element OLED may receive a first voltage ELVDD through the first transistor T1, and the cathode of the light emitting element OLED may receive a second voltage ELVSS. The light emitting element OLED may receive the first voltage ELVDD and the second voltage ELVSS to emit light.

The first transistor T1 may include a drain D1 receiving the first voltage ELVDD, a source S1 connected to the anode of the light emitting element OLED, and a gate G1 connected to the capacitor Cst. The first transistor T1 may control a driving current flowing through the light emitting element OLED from the first voltage ELVDD in response to voltage values stored in the capacitor Cst.

The second transistor T2 may include a drain D2 connected to the j-th data line DLj, a source S2 connected to the capacitor Cst, and a gate G2 receiving the i-th first scan signal SCi. The j-th data line DLj may receive a data voltage Vd. The second transistor T2 may provide the data voltage Vd to the first transistor T1 in response to the i-th first scan signal SCi.

The third transistor T3 may include a source S3 connected to the j-th reference line RLj, a drain D3 connected to the anode of the light emitting element OLED, and a gate G3 receiving the i-th second scan signal SSi. The j-th reference line RLj may receive a reference voltage Vr. The third transistor T3 may initialize the capacitor Cst and the anode of the light emitting element OLED.

The capacitor Cst may store a voltage corresponding to a difference between a voltage received from the second transistor T2 and the first voltage ELVDD. The capacitor Cst may be connected to the gate G1 of the first transistor T1 and the anode of the light emitting element OLED.

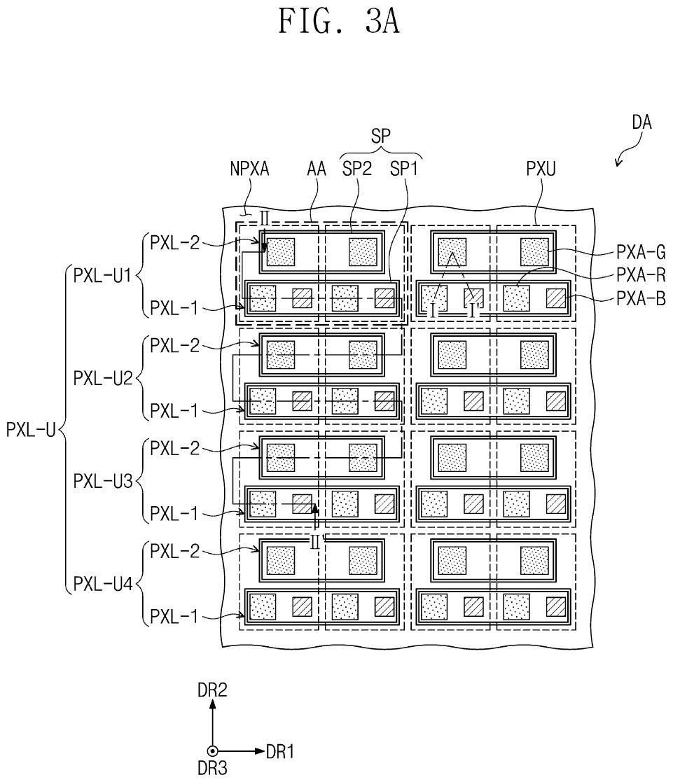

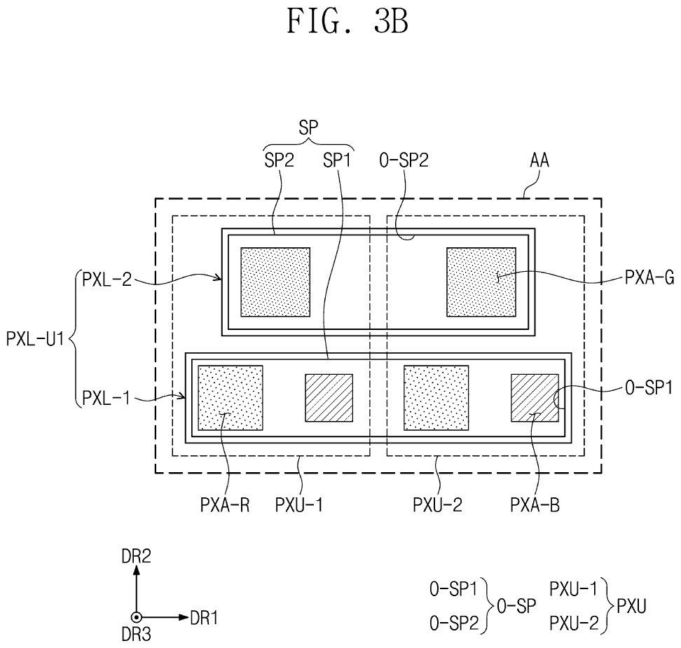

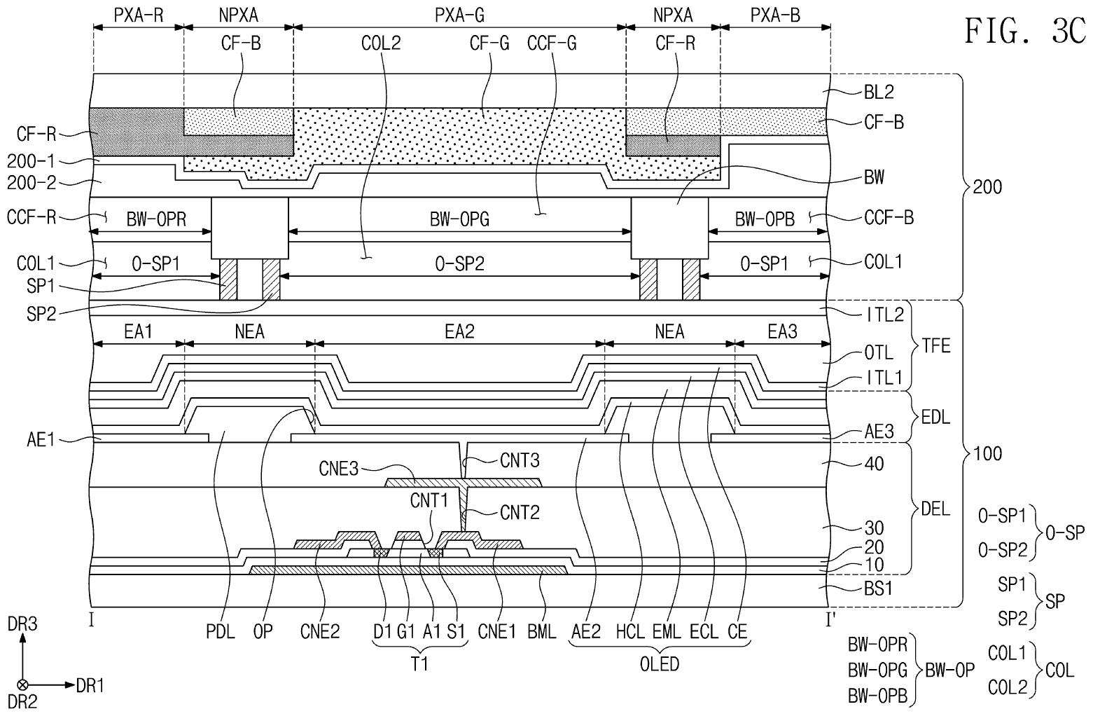

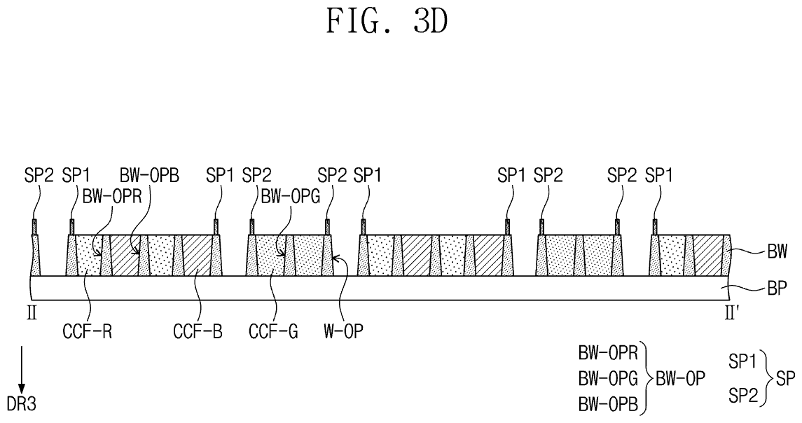

FIG. 3A is an enlarged plan view of the display region DA according to an embodiment of the disclosure. FIG. 3B is an enlarged plan view of a display region DA according to an embodiment of the disclosure, which corresponds to region AA shown in FIG. 3A. FIG. 3C is a schematic cross-sectional view corresponding to I-I′ of FIG. 3A. FIG. 3D is a schematic cross-sectional view corresponding to II-II′ of FIG. 3A. In FIG. 3D, only a second insulating layer 200-2, a barrier rib BW, and light conversion patterns CCF-R, CCF-G, and CCF-B among components included in the light conversion panel 200 are shown. FIG. 3D shows a state in which some components included in the light conversion panel 200 shown in FIG. 3C are vertically inverted for convenience of description.

Multiple pixel regions PXA-R, PXA-G, and PXA-B shown in FIG. 3A are shown as viewed from an outer surface 200-OS of the light conversion panel 200 shown in FIG. 1B. A peripheral region NPXA may be disposed adjacent to the pixel regions PXA-R, PXA-G, and PXA-B. The peripheral region NPXA may set a boundary between the first to third pixel regions PXA-R, PXA-G, and PXA-B, and prevent the first to third pixel regions PXA-R, PXA-G, and PXA-B from being color-mixed. The pixel regions PXA-R, PXA-G, and PXA-B may be included in multiple pixel rows PXL-1 and PXL-2 extending in the first direction DR1.

Referring to FIGS. 1B, 3A, and 3B, the first pixel region PXA-R and the third pixel region PXA-B may be arranged in a same row, and the second pixel region PXA-G may be disposed in a different row from the first pixel region PXA-R and the third pixel region PXA-B. The second pixel region PXA-G may have a largest area and the third pixel region PXA-B may have a smallest area in a plan view, but the disclosure is not limited thereto. In the embodiment, the first pixel region PXA-R, the second pixel region PXA-G, and the third pixel region PXA-B having a substantially square shape are shown as an embodiment, but the disclosure is not limited thereto. In a plan view, the first to third pixel regions PXA-R, PXA-G, and PXA-B may have other polygonal shapes such as a rhombus or a pentagon.

The first to third pixel regions PXA-R, PXA-G, and PXA-B may provide light of different colors onto the outer surface 200-OS of the light conversion panel 200. The first pixel region PXA-R may provide red light onto the outer surface 200-OS of the light conversion panel 200, the second pixel region PXA-G may provide green light, and the third pixel region PXA-B may provide blue light.

In the embodiment, the pixel rows PXL-1 and PXL-2 may be divided into two groups. The pixel rows PXL-1 and PXL-2 may include first pixel rows PXL-1 and second pixel rows PXL-2, which are disposed to be apart in the second direction DR2. In the second direction DR2, the first pixel rows PXL-1 and the second pixel rows PXL-2 may be alternately disposed.

Each of the first pixel rows PXL-1 may include first pixel regions PXA-R and third pixel regions PXA-B, which are alternately disposed in the first direction DR1. Each of the first pixel rows PXL-1 may have a same arrangement of pixel regions. Each of the second pixel rows PXL-2 may include second pixel regions PXA-G arranged in the first direction DR1. Each of the second pixel rows PXL-2 may have a same arrangement of pixel regions. One second pixel region PXA-G may be disposed to correspond to a pair of the first pixel region PXA-R and the third pixel region PXA-B. The second pixel region PXA-G may be disposed to be spaced apart from the first pixel region PXA-R and the third pixel region PXA-B in the second direction DR2. In the first direction DR1, the second pixel region PXA-G may be disposed between the first pixel region PXA-R and the third pixel region PXA-B.

Among the pixel regions PXA-R, PXA-G, and PXA-B, one first pixel region PXA-R, one second pixel region PXA-G, and one third pixel region PXA-B may form one unit pixel PXU. One first pixel row PXL-1 and one second pixel row PXL-2 may define one unit pixel row PXL-U. The unit pixel rows PXL-U may be arranged in the second direction DR2. In one unit pixel row PXL-U, multiple unit pixels PXU may be arranged in the first direction DR1. FIG. 3A shows a first unit pixel row PXL-U1, a second unit pixel row PXL-U2, a third unit pixel row PXL-U3, and a fourth unit pixel row PXL-U4. Arrangement patterns of the first pixel region PXA-R, the second pixel region PXA-G, and the third pixel region PXA-B of the unit pixels PXU in each of the unit pixel rows PXL-U1, PXL-U2, PXL-U3, and PXL-U4 may be the same.

FIG. 3C schematically shows a cross-section corresponding to the second pixel region PXA-G, and schematically shows a cross-section of the first transistor T1. A stack structure of the first pixel region PXA-R and the third pixel region PXA-B may be similar to that of the second pixel region PXA-G shown in FIG. 3C.

Referring to FIG. 3C, the display panel 100 may include a first base layer BS1, a circuit layer DEL, a display element layer EDL, and an encapsulation layer TFE. The circuit layer DEL may be disposed on the first base layer BS1. The circuit layer DEL may include multiple insulating layers, multiple conductive layers, and a semiconductor layer. The display element layer EDL may be disposed on the circuit layer DEL. The encapsulation layer TFE may be disposed on the display element layer EDL and may encapsulate the display element layer EDL.

The first base layer BS1 may include glass or a synthetic resin film. The synthetic resin layer may include a thermosetting resin. For example, the synthetic resin layer may be a polyimide-based resin layer, and the material is not particularly limited. The synthetic resin layer may include at least one of an acryl-based resin, a methacryl-based resin, polyisoprene, a vinyl-based resin, an epoxy-based resin, a urethane-based resin, a cellulose-based resin, a siloxane-based resin, a polyamide-based resin, and a perylene-based resin. The base layer may include a glass substrate, a metal substrate, or an organic/inorganic composite material substrate.

A light blocking pattern BML may be disposed on the first base layer BS1. The light blocking pattern BML may include a metal. A signal line and the light blocking pattern BML may be disposed on a same layer. A first insulating layer 10 covering the light blocking pattern BML may be disposed on the first base layer BS1.

A semiconductor pattern overlapping the light blocking pattern BML in a plan view may be disposed on the first insulating layer 10. The semiconductor pattern may have different electrical properties according to doping. The semiconductor pattern may include a first region having high conductivity and a second region having low conductivity. The first region may be doped with an N-type dopant or a P-type dopant. A P-type transistor may include a doped region doped with a P-type dopant, and a N-type transistor may include a doped region doped with an N-type dopant. The second region may be a non-doped region or may be doped in a lower concentration than the first region.

The semiconductor pattern may include a source region S1, a channel region A1 (or an active region), and a drain region D1. A second insulating layer 20 may be disposed on the first insulating layer 10. Contact holes CNT1 exposing the source region S1 and the drain region D1 may be defined in the second insulating layer 20. The first insulating layer 10 and the second insulating layer 20 may be inorganic layers.

Connection electrodes CNE1 and CNE2 may be disposed on the second insulating layer 20. The first connection electrode CNE1 may electrically connect the source region S1 of the first transistor T1 to the drain D3 of the third transistor T3 shown in FIG. 2. The second connection electrode CNE2 electrically may connect the drain region D1 of the first transistor T1 to the signal line receiving the first voltage ELVDD shown in FIG. 2. The gate G1 of the first transistor T1 and the connection electrodes CNE1 and CNE2 may be disposed on a same layer. The gate G1 of the first transistor T1 may overlap a channel region A1 in a plan view.

A third insulating layer 30 may be disposed on the second insulating layer 20. A third connection electrode CNE3 may be disposed on the third insulating layer 30. The third connection electrode CNE3 may be connected to the first connection electrode CNE1 through a contact hole CNT2 passing through the third insulating layer 30. A fourth insulating layer 40 may be disposed on the third insulating layer 30.

A display element layer EDL may be disposed on the fourth insulating layer 40. The display element layer EDL may include a light emitting element OLED as a display element. The light emitting element OLED may generate the source light described above. The light emitting element OLED may include first electrodes AE1, AE2, and AE3, a second electrode EL2, and an emission layer EML disposed between the first electrodes AE1, AE2, and AE3 and the second electrode EL2. In the embodiment, the display element layer EDL may include an organic light emitting diode as a light emitting element. In an embodiment of the disclosure, the light emitting element may include a quantum dot light emitting diode. For example, the emission layer EML included in the light emitting element OLED may include an organic light emitting material as a light emitting material, or the emission layer EML may include quantum dots as a light emitting material. In another embodiment, unlike what is shown in FIG. 3C, the display element layer EDL may include an ultra-small light emitting element as a light emitting element. The ultra-small light emitting element may include, for example, a micro LED element and/or a nano LED element, or the like. The ultra-small light emitting element may be a light emitting element having a micro- or nano-scale size and including an active layer disposed between multiple semiconductor layers.

The first electrodes AE1, AE2, and AE3 may be disposed on the fourth insulating layer 40. The first electrodes AE1, AE2, and AE3 may be connected to the third connection electrode CNE3 through a contact hole CNT3 passing through the fourth insulating layer 40. The third insulating layer 30 and the fourth insulating layer 40 may be organic layers. The first electrodes AE1 and AE3 of the first pixel region PXA-R and the third pixel region PXA-B and the first electrode AE2 of the second pixel region PXA-G may be disposed on a same layer.

The light emitting element OLED and a pixel defining film PDL may be disposed on the fourth insulating layer 40. The pixel defining film PDL may be disposed on the circuit element layer DEL and may cover a portion of the first electrodes AE1, AE2, and AE3. A light emitting opening OP may be defined in the pixel defining film PDL. The light emitting opening OP of the pixel defining film PDL may expose at least a portion of the first electrodes AE1 and AE3. The light emitting openings OP of the pixel defining film PDL may define light emitting regions EA1, EA2, and EA3 to correspond to the first electrodes AE1, AE2, and AE3 of the first pixel region PXA-R, the second pixel region PXA-G, and the third pixel region PXA-B. A region between the light emitting regions EA1, EA2, and EA3, for example, a region in which the pixel defining film PDL is disposed may be defined as a non-light emitting region NEA.

The display element layer EDL may include a first light emitting region EA1, a second light emitting region EA2, and a third light emitting region EA3. The first light emitting region EA1, the second light emitting region EA2, and the third light emitting region EA3 may be regions divided by the pixel defining film PDL. The first light emitting region EA1, the second light emitting region EA2, and the third light emitting region EA3 may correspond to the first pixel region PXA-R, the second pixel region PXA-G, and the third pixel region PXA-B, respectively. In a plan view, areas of the pixel regions PXA-R, PXA-B, and PXA-G may be greater than areas of the light emitting regions EA1, EA2, and EA3 divided by the pixel defining film PDL in a plan view.

In the light emitting element OLED, the first electrodes AE1, AE2, and AE3 may be disposed on the circuit layer DEL. The first electrodes AE1, AE2, and AE3 may be an anode or a cathode. The first electrodes AE1, AE2, and AE3 may be a pixel electrode. The first electrodes AE1, AE2, and AE3 may be a transmissive electrode, a transflective electrode, or a reflective electrode.

A hole control layer HCL may be disposed between the first electrodes AE1, AE2, and AE3, and an emission layer EML. The hole control layer HCL may include at least one of a hole injection layer, a hole transport layer, and an electron blocking layer. The hole control layer HCL may be disposed as a common layer to overlap the light emitting regions EA1, EA2, and EA3, and the entirety of the pixel defining film PDL that separates the light emitting regions EA1, EA2, and EA3. However, the disclosure is not limited thereto, and the hole control layer HCL may be provided through patterning so that the hole control layer HCL is separately disposed corresponding to each of the light emitting regions EA1, EA2, and EA3.

The emission layer EML may be disposed on the hole control layer HCL. The emission layer EML may be commonly disposed in the light emitting regions EA1, EA2, and EA3 and the non-light emitting region NEA. In an embodiment, the emission layer EML may be provided as a common layer to overlap the light emitting regions EA1, EA2, and EA3, and the entirety of the pixel defining film PDL that separates the light emitting regions EA1, EA2, and EA3. In an embodiment, the emission layer EML may emit blue light as a source light. The emission layer EML may overlap an entire area of the hole control layer HCL and the electron control layer ECL in a plan view.

However, the disclosure is not limited thereto, and in an embodiment, the emission layer EML may be disposed in the light emitting opening OP. For example, the emission layers EML may be separately formed to correspond to the light emitting regions EA1, EA2, and EA3 which are separated by the pixel defining film PDL. The emission layers EML formed separately to correspond to the light emitting regions EA1, EA2, and EA3 may all emit blue light or may emit light having different wavelength ranges.

The emission layer EML may have a single layer formed of a single material, a single layer formed of multiple materials different from each other, or a multi-layered structure that has multiple layers formed of multiple materials different from each other. The emission layer EML may include a fluorescent or phosphorescent material. In the light emitting element according to an embodiment, the emission layer EML may include an organic light emitting material, a metal organic complex, or quantum dots as a light emitting material. FIG. 3C shows, as an embodiment, a light emitting element OLED including one emission layer EML, but the disclosure is not limited thereto, and in an embodiment, the light emitting element may include multiple light emitting stacks each having at least one emission layer.

The electron control layer ECL may be disposed between the emission layer EML and the second electrode EL2. The electron control layer ECL may include at least one of an electron injection layer, an electron transport layer, and a hole blocking layer. The electron control layer ECL may be disposed as a common layer to overlap the light emitting regions EA1, EA2, and EA3, and an entire area of the pixel defining film PDL that separates the light emitting regions EA1, EA2, and EA3 in a plan view. However, the disclosure is not limited thereto, and the electron control layer ECL may be provided through patterning so that the electron control layer ECL is separately disposed corresponding to each of the light emitting regions EA1, EA2, and EA3.

The second electrode CE may be provided onto the electron control layer ECL. The second electrode CE may be a common electrode. The second electrode CE may be a cathode or an anode, but the disclosure is not limited thereto. For example, in case that the first electrodes AE1, AE2, and AE3 are anodes, the second electrode EL2 may be a cathode, and in case that the first electrodes AE1, AE2, and AE3 are cathodes, the second electrode EL2 may be an anode. The second electrode CE may be a transmissive electrode, a transflective electrode, or a reflective electrode. Although not shown, the light emitting element OLED may further include a capping layer (not shown) disposed on an upper portion of the second electrode CE.

The encapsulation layer TFE may be disposed on the light emitting element OLED. For example, in an embodiment, the encapsulation layer TFE may be disposed on the second electrode CE. In case that the light emitting element OLED includes a capping layer (not shown), the encapsulation layer TFE may be disposed on the capping layer (not shown).

The encapsulation layer TFE may include at least an inorganic layer or an organic layer. The encapsulation layer TFE may include a first inorganic encapsulation layer ITL1, an organic encapsulation layer OTL, and a second inorganic encapsulation layer ITL2, which are sequentially stacked. The organic encapsulation layer OTL may be disposed between the first inorganic encapsulation layer ITL1 and the second inorganic encapsulation layer ITL2. The first inorganic encapsulation layer ITL1 and the second inorganic encapsulation layer ITL2 may protect the display element layer EDL against moisture/oxygen, and the organic encapsulation layer OTL may protect the display element layer EDL against impurities such as dust particles. The first inorganic encapsulation layer ITL1 and the second inorganic encapsulation layer ITL2 may include at least one of silicon nitride, silicon oxynitride, silicon oxide, titanium oxide, and aluminum oxide. The organic encapsulation layer OTL may include a polymer, for example, an acryl-based organic material. However, the disclosure is not limited thereto.

FIG. 3C shows that the encapsulation layer TFE includes two inorganic layers and one organic layer as an embodiment, but the disclosure is not limited thereto. For example, the encapsulation layer TFE may include three inorganic layers and two organic layers, and may have a structure in which the inorganic layers and the organic layers are alternately stacked each other. Although not shown, the display panel 100 may further include a refractive index control layer on an upper side of the encapsulation layer TFE to increase light output efficiency.

The light conversion panel 200 may include a second base layer BL2, color filters CF-R, CF-G, CF-B sequentially disposed on a lower surface of the second base layer BL2, light conversion patterns CCF-R, CCF-G, and CCF-B, a barrier rib BW, a division pattern SP, an organic pattern COL, and multiple insulating layers 200-1 and 200-2. The insulating layers 200-1 and 200-2 may be organic layers or inorganic layers.

The second base layer BL2 may be a member providing a reference plane on which the color filters CF-R, CF-G, and CF-B, the second insulating layer 200-2, and the light conversion patterns CCF-R, CCF-G, and CCF-B are disposed. The second base layer BL2 may be a glass substrate, a metal substrate, a plastic substrate, or the like. However, the disclosure is not limited thereto, and the second base layer BL2 may be an inorganic layer, an organic layer, or a composite material layer. In another embodiment, the second base layer BL2 may be omitted.

Although not shown, an anti-reflection layer may be disposed on the second base layer BL2. The anti-reflection layer may be a layer that reduces the reflectance of external light incident from the outside. The anti-reflection layer may be a layer that selectively transmits light emitted from the display panel DP. In an embodiment, the anti-reflection layer may be a single layer including a dye and/or a pigment dispersed in a base resin. The anti-reflection layer may be provided as one continuous layer that overlaps the entire surfaces of the first to third pixel regions PXA-R, PXA-G, and PXA-B in a plan view.

The anti-reflection layer may not include a polarizing layer. Accordingly, light that passes through the anti-reflection layer and is incident on the side of the display element layer EDL may be unpolarized light. The display element layer EDL may receive unpolarized light from above the anti-reflection layer.

The color filters CF-R, CF-G, and CF-B may be disposed below the second base layer BL2. The color filters CF-R, CF-G, and CF-B may be disposed between the second base layer BL2 and the light conversion patterns CCF-R, CCF-G, and CCF-B.

The color filters CF-R, CF-G, and CF-B may include a first color filter CF-R, a second color filter CF-G, and a third color filter CF-B. The first color filter CF-R may be disposed to overlap the first light emitting region EA1 in a plan view, the second color filter CF-G may be disposed to overlap the second light emitting region EA2 in a plan view, and the third color filter CF-B may be disposed to overlap the third light emitting region EA3 in a plan view. The color filters CF-R, CF-G, and CF-B may transmit light having a specific wavelength range and block light having a wavelength other than the specific wavelength range. The first color filter CF-R may transmit the first color light and block the second color light and the third color light. The second color filter CF-G may transmit the second color light and block the first color light and the third color light. The third color filter CF-B may transmit the third color light and block the first color light and the second color light. The first color light may be red light. The second color light may be green light. The source light may be third color light. The third color light may be blue light.

The first color filter CF-R, the second color filter CF-G, and the third color filter CF-B may define the first pixel region PXA-R, the second pixel region PXA-G, the third pixel region PXA-B, and the peripheral region NPXA. A region in which two or more color filters of the first color filter CF-R, the second color filter CF-G, and the third color filter CF-B overlap in a plan view may be defined as the peripheral region NPXA. In each of the first pixel region PXA-R, the second pixel region PXA-G, and the third pixel region PXA-B, only a corresponding color filter among the first color filter CF-R, the second color filter CF-G, and the third color filter CF-B may be disposed. In case that a black mattress pattern is further disposed, the peripheral region NPXA may be defined as a region in which a black mattress pattern is disposed.

The color filters CF-R, CF-G, and CF-B may each include a base resin and a dye and/or a pigment dispersed in the base resin. The base resin may be a medium in which dyes and/or pigments are dispersed, and may be formed of various resin compositions that may be generally referred to as binders.

The color filters CF-R, CF-G, and CF-B may each have a uniform thickness in a corresponding pixel region. The first color filter CF-R may have a uniform thickness in the first pixel region PXA-R. Accordingly, light converted from blue, source light to red light through the first color filter CF-R may be provided to the outside with uniform luminance in the first pixel region PXA-R. The second color filter CF-G may have a uniform thickness in the second pixel region PXA-G. Accordingly, light converted from blue, source light to green light through the second color filter CF-G may be provided to the outside with uniform luminance in the second pixel region PXA-G. The third color filter CF-B may have a uniform thickness in the third pixel region PXA-B. Through the third color filter CF-B, the source light, which is blue light may be provided to the outside with uniform luminance in the third pixel region PXA-B.

The first insulating layer 200-1 may be disposed below the first color filter CF-R, the second color filter CF-G, and the third color filter CF-B, and may cover the first color filter CF-R, the second color filter CF-G, and the third color filter CF-B. The second insulating layer 200-2 may cover the first insulating layer 200-1 and may provide a flat surface on a lower side.

The second insulating layer 200-2 may be a low refractive layer. The second insulating layer 200-2 may be disposed between the light conversion patterns CCF-R, CCF-G, and CCF-B and the color filters CF-R, CF-G, and CF-B. The second insulating layer 200-2 may be disposed on an upper portion of the light conversion patterns CCF-R, CCF-G, and CCF-B to prevent the light conversion patterns CCF-R, CCF-G, and CCF-B from being exposed to moisture/oxygen. The second insulating layer 200-2 may be disposed between the first light conversion patterns CCF-R, CCF-G, and CCF-B, and the color filters CF-R, CF-G, and CF-B to serve as an optical functional layer that increases light extraction efficiency or prevents reflected light from entering the light conversion patterns CCF-R, CCF-G, and CCF-B. The second insulating layer 200-2 may have a smaller refractive index than a refractive index of a layer adjacent thereto. The second insulating layer 200-2 may be an organic layer or an inorganic layer.

The barrier rib BW may be disposed below the second insulating layer 200-2. In a plan view, the barrier rib BW may overlap the peripheral region NPXA. First openings BW-OP may be defined in the barrier rib BW. The first openings BW-OP may each correspond to the first pixel region PXA-R, the second pixel region PXA-G, and the third pixel region PXA-B, and may each correspond to the first light emitting region EA1, the second light emitting region EA2, and the third light emitting region EA3. “Correspond” may indicate that two components overlap in a plan view, and is not limited to the same area.

The barrier rib BW may include a material having a transmittance of a predetermined value or less. For example, the barrier rib BW may include a light blocking material, for example, a black component. The barrier rib BW may include a black dye and/or a black pigment mixed with a base resin. For example, the barrier rib BW may include at least one of propylene glycol methyl ether acetate, 3-methoxy-n-butyl acetate, an acrylate monomer, an acrylic monomer, an organic pigment, and acrylate ester.

Referring to FIGS. 3C and 3D, the light conversion patterns CCF-R, CCF-G, and CCF-B may include the first light conversion pattern CCF-R, the second light conversion pattern CCF-G, and the third light conversion pattern CCF-B, each of which is disposed in the first openings BW-OP. Herein, the third light conversion pattern CCF-B may be referred to as a “transmission pattern”.

The first light conversion pattern CCF-R, the second light conversion pattern CCF-G, and the transmission pattern CCF-B may each be disposed to correspond to the first pixel region PXA-R, the second pixel region PXA-G, and the third pixel region PXA-B. The first openings BW-OP may include a (1-1)-th opening BW-OPR overlapping the first pixel region PXA-R in a plan view, a (1-2)-th opening BW-OPG overlapping the second pixel region PXA-G in a plan view, and a (1-3)-th opening BW-OPB overlapping the third pixel region PXA-B in a plan view. The first light conversion pattern CCF-R may be disposed inside the (1-1)-th opening BW-OPR, and the second light conversion pattern CCF-G may be disposed inside the (1-2)-th opening BW-OPG, and the transmission pattern CCF-B may be disposed inside the (1-3)-th opening BW-OPB.

The first light conversion pattern CCF-R may convert the source light into first color light. The second light conversion pattern CCF-G may convert the source light into second color light.

The transmission pattern CCF-B may transmit the source light without converting the light into other color light. The transmission pattern CCF-B may include a transparent base resin. The transmission pattern CCF-B may further include scattering particles mixed with the base resin. The scattering particles may scatter the source light passing through the transmission pattern SP and broaden a viewing angle of the third pixel region PXA-B.

Each of the first light conversion pattern CCF-R and the second light conversion pattern CCF-G may be formed through an inkjet process. The first light conversion pattern CCF-R and the second light conversion pattern CCF-G may be formed as liquid ink compositions provided onto a space defined by the barrier rib BW, for example, each of the (1-1)-th openings BW-OPR and the (1-2)-th openings BW-OPG. A liquid ink composition that is polymerized through a thermal curing process or a photo-curing process may be reduced in volume after being cured.

The transmission pattern CCF-B may be formed through a photolithography process. During the light conversion patterns CCF-R, CCF-G, and CCF-B are formed, the transmission pattern CCF-B may be formed using a photolithography process, and the first light conversion pattern CCF-R and the second light conversion pattern CCF-G may be formed using an inkjet process.

In case that the first light conversion pattern CCF-R and the second light conversion pattern CCF-G are formed using a different process from the transmission pattern CCF-B, the first light conversion pattern CCF-R and the second light conversion pattern CCF-R may have different structural characteristics from the transmission pattern CCF-B.

A thickness of each of the first and second light conversion patterns CCF-R and CCF-G may be smaller than a thickness of the transmission pattern CCF-B overlapping the third pixel region PXA-B. A first composition for forming the first light conversion pattern CCF-R and a second composition for forming the second light conversion pattern CCF-G may each be provided in the (1-1)-th opening BW-OPR and the (1-2)-th opening BW-OPG, and may be reduced in thickness through curing or drying. Accordingly, the thickness of each of the first light conversion pattern CCF-R and the second light conversion pattern CCF-G formed through an inkjet process may be smaller than the thickness of the transmission pattern CCF-B formed through a photolithography process.

The transmission pattern CCF-B may be formed through a photolithography process, and may thus have an upper surface, which is flatter than upper surfaces of each of the first and second light conversion patterns CCF-R and CCF-G. Each of the first light conversion pattern CCF-R and the second light conversion pattern CCF-G may be subjected to a curing or drying process after a liquid composition is provided, and may thus have a relatively curved upper surface. For example, the upper surface of the transmission pattern CCF-B may be flatter than the upper surfaces of the first light conversion pattern CCF-R and the second light conversion pattern CCF-G.

The transmission pattern CCF-B may be formed to correspond to each of the third pixel regions PXA-B through a single photolithography process. Therefore, a thickness deviation of the transmission patterns CCF-B may be smaller than a thickness deviation of the first light conversion pattern CCF-R and the second light conversion pattern CCF-G. Each of the first light conversion patterns CCF-R and the second light conversion patterns CCF-G may be formed by providing a liquid composition to each of the first pixel regions PXA-R and the second pixel regions PXA-G. The liquid composition may be provided discontinuously, and accordingly, a weight variation of the provided liquid composition may be caused. Accordingly, the thickness deviation of each of the first and second light conversion patterns CCF-R and CCF-G may be relatively greater than the thickness deviation of the transmission patterns CCF-B.

Referring to FIGS. 3A to 3D, the display device DD according to an embodiment may include a division pattern SP overlapping the peripheral region NPXA in a plan view and surrounding a corresponding pixel region among the pixel regions PXA-R, PXA-G, and PXA-B. In a plan view defined by the first direction DR1 and the second direction DR2, the division pattern SP may surround a corresponding light emitting region among the first pixel region PXA-R, the second pixel region PXA-G, and the third pixel region PXA-B. The division pattern SP may serve to prevent an ink composition from overflowing into adjacent light emitting regions during an inkjet process for forming a light conversion pattern.

The division pattern SP may be disposed on the barrier rib BW to serve to separate at least one of the pixel regions PXA-R, PXA-G, and PXA-B from other pixel regions. The division pattern SP may be disposed on the barrier rib BW to surround at least one pixel region among the pixel regions PXA-R, PXA-G, and PXA-B in a plan view, and thus, at least one pixel region may be separated from other pixel regions. In another embodiment, the division pattern SP may serve to separate each of the light emitting regions PXA-R, PXA-G, and PXA-B. For example, the division pattern SP may surround each of the first pixel region PXA-R, the second pixel region PXA-G, and the third pixel region PXA-B.

Referring to FIG. 3A, the pixel regions PXA-R, PXA-G, and PXA-B included in a first pixel row PXL-1 and a second pixel row PXL-2 may be divided into multiple pixel region groups. The pixel regions PXA-R, PXA-G, and PXA-B may be divided into multiple pixel region groups by the division pattern SP.

The first pixel row PXL-1 may include multiple first pixel region groups including n first pixel regions PXA-R. In the first pixel row PXL-1, each of the first pixel region groups may include n first pixel regions PXA-R. n may be an integer of 2 or greater. For example, n may be 2. For example, the first pixel row PXL-1 may include first pixel region groups each including two or more first pixel regions PXA-R.

In the first pixel row PXL-1, the first pixel region group may include a first pixel region PXA-R and a third pixel region PXA-B. As shown in FIG. 3A, in the first pixel row PXL-1, the first pixel region PXA-R and the third pixel region PXA-B may be alternately disposed along the first direction DR1, and accordingly, the first pixel region group may include the first pixel region PXA-R and the third pixel region PXA-B. In the first pixel row PXL-1, the first pixel region group may include n first pixel regions PXA-R and n+a third pixel regions PXA-B. a may be −1 or 0. For example, a may be 0.

The second pixel row PXL-2 may include multiple second pixel region groups including m second pixel regions PXA-G. Each of the second pixel region groups may include m second pixel regions PXA-G. m may be an integer of 2 or greater. For example, m may be 2. For example, the second pixel row PXL-2 may include second pixel region groups each including two or more second pixel regions PXA-G.

As shown in FIG. 3A, the division pattern SP may surround the first pixel region PXA-R and the third pixel region PXA-B, which are disposed in the first pixel row PXL-1, and may surround the second pixel region PXA-G disposed in the second pixel row PXL-2. For example, the division pattern SP may include a first division pattern SP1 surrounding the first pixel region PXA-R and the third pixel region PXA-B, which are disposed in the first pixel row PXL-1, and a second division pattern SP2 surrounding the second pixel region PXA-G disposed in the second pixel row PXL-2.

The first division pattern SP1 may surround a first pixel region group including n first pixel regions PXA-R in the first pixel row PXL-1. Each of the first pixel region groups in the first pixel row PXL-1 may include n first pixel regions PXA-R, and the first division pattern SP1 may completely surround each of the first pixel region groups in a plan view defined by the first direction DR1 and the second direction DR2.

The first division pattern SP1 may surround a first pixel region group including n first pixel regions PXA-R and n+a third pixel regions PXA-B in the first pixel row PXL-1. Each of the first pixel region groups in the first pixel row PXL-1 may include n first pixel regions PXA-R and n+a third pixel regions PXA-B, and each of the first pixel region groups may be surrounded by the first division pattern SP1. n may be an integer of 2 or greater, and a may be −1 or 0. FIG. 3A shows an embodiment in which n is 2 and a is 0, but the disclosure is not limited thereto. Unlike what is shown in FIGS. 3A and 3B, in case that a is −1, it may indicate that a portion of the third pixel region PXA-B included in the first pixel row PXL-1 is not surrounded by the first division pattern SP1. In case that the transmission pattern CCF-B corresponding to the third pixel region PXA-B is formed through a photolithography process, at least a portion of the third pixel region PXA-B may not be required to be separated from other pixel regions by the division pattern SP. Accordingly, a portion of the third pixel region PXA-B overlapping the transmission pattern CCF-B may not be surrounded by the division pattern SP.

As described above, the transmission pattern CCF-B corresponding to the third pixel region PXA-B may be formed through a photolithography process. Accordingly, even in case that the first pixel region PXA-R and the third pixel region PXA-B are surrounded by one division pattern SP, color mixing of ink compositions between adjacent pixels may not be caused during an inkjet process. For example, as the transmission pattern CCF-B is formed through the photolithography process before the inkjet process for forming the first and second light conversion patterns CCF-R and CCF-G, only the liquid composition for forming the first light conversion pattern CCF-R may be provided at a position corresponding to the first division pattern SP1, and accordingly, color mixing of ink compositions between pixels included in the first pixel row PXL-1 and the second pixel row PXL-2 may be prevented.

As the first pixel regions PXA-R are divided into first pixel region groups including n first pixel regions PXA-R by the first division pattern SP1, ink color mixing between neighboring pixels during the inkjet process may be prevented in the forming of the light conversion patterns CCF-R and CCF-G. The ink may be concurrently dripped onto portions corresponding to n first pixel regions PXA-R, and thus the number of processes may be reduced compared to a method of dripping an ink composition onto individual pixel regions. Accordingly, the inkjet process for forming the light conversion patterns CCF-R and CCF-G may be provided with reduced turn around time (TAT) to improve process efficiency.

The second division pattern SP2 may surround a second pixel region group including m second pixel regions PXA-G in the second pixel row PXL-2. The second pixel row PXL-2 may include multiple second pixel region groups including m second pixel regions PXA-G, and the second division pattern SP2 may completely surround each of the second pixel region groups in a plan view defined by the first direction DR1 and the second direction DR2. m may be an integer of 2 or greater. FIG. 3A shows an embodiment in which m is 2, but the disclosure is not limited thereto.

As the second pixel regions PXA-G are divided into second pixel region groups including m second pixel regions PXA-G by the second division pattern SP2, ink color mixing between neighboring pixels during the inkjet process may be prevented in the forming of the light conversion patterns CCF-R and CCF-G. The ink may be concurrently dripped onto portions corresponding to m second pixel regions PXA-R, and thus the number of processes may be reduced compared to a method of dripping an ink composition onto individual pixel regions. Accordingly, the inkjet process for forming the light conversion patterns CCF-R and CCF-G may be provided with reduced turn around time (TAT) to improve process efficiency.

In an embodiment, the division pattern SP and the transmission pattern CCF-B may be formed through a same process. The division pattern SP and the transmission pattern CCF-B may be formed through a photolithography process. The division pattern SP and the transmission pattern CCF-B may be formed through a single photolithography process. In case that the light conversion patterns CCF-R, CCF-G, and CCF-B are formed, the division pattern SP and the transmission pattern CCF-B may be formed using a photolithography process, and the first light conversion pattern CCF-R and the second light conversion pattern CCF-G may be formed using an inkjet process.

The division pattern SP and the transmission pattern CCF-B corresponding to the third pixel region PXA-B may include a same material. As the division pattern SP is formed through the same process as the transmission pattern CCF-B, the division pattern SP and the transmission pattern CCF-B may include a same material. For example, the division pattern SP may include a base resin. The base resin may include a photosensitive material. The division pattern SP may further include scattering particles mixed with the base resin. The scattering particles may be titanium oxide (TiO₂) or silica-based nanoparticles.

Referring to FIGS. 3B to 3D, in the division pattern SP, a division opening O-SP overlapping a corresponding pixel region among the first pixel region PXA-R, the second pixel region PXA-G, and the third pixel region PXA-B may be defined. As shown in FIG. 3B, a first division opening O-SP1 overlapping the first pixel region PXA-R included in the first pixel row PXL-1 may be defined in the first division pattern SP1, and a second division opening O-SP2 overlapping the second pixel region PXA-G included in the second pixel row PXL-2 may be defined in the second division pattern SP2.

Referring to FIG. 3B, the first division opening O-SP1 may overlap the first pixel region PXA-R and the third pixel region PXA-B included in the first pixel region group in the first pixel row PXL-1. For example, as shown in FIG. 3B, the first division opening O-SP1 may overlap a first pixel region PXA-R and a third pixel region PXA-B included in one unit pixel PXU-1 (hereinafter referred to as a first unit pixel), and a first pixel region PXA-R and a third pixel region PXA-B included in a unit pixel PXU-2 (hereinafter referred to as a second unit pixel) adjacent to the first unit pixel PXU-1 in the first direction DR1.

The second division opening O-SP2 may overlap the second pixel region PXA-G included in the second pixel region group in the second pixel row PXL-2. The second division opening O-SP2 may overlap a second pixel region PXA-G included in the first unit pixel PXU-1, and the second pixel region PXA-G included in the second unit pixel PXU-2.

In a plan view defined by the first direction DR1 and the second direction DR2, areas of the division openings O-SP1 and O-SP2 may be greater than areas of each of the first openings BW-OP defined in the barrier rib BW. A planar area of the first division opening O-SP1 may be greater than a planar area of each of (1-1)-th openings BW-OPR defined to correspond to the first pixel region PXA-R, and (1-3)-th openings BW-OPB defined to correspond to the third pixel region PXA-B. A planar area of the second division opening O-SP2 may be greater than a planar area of (1-2)-th openings BW-OPG defined to correspond to the second pixel region PXA-G.

The display device DD according to an embodiment may further include an organic pattern COL disposed in the division opening O-SP defined in the division pattern SP. The display device DD according to an embodiment may include a display panel 100 including a display element layer EDL, and a light conversion panel 200 including light conversion patterns CCF-R, CCF-G, and CCF-B and color filters CF-R, CF-G, and CF-B, and the organic pattern COL may be disposed between the display panel 100 and the light conversion patterns CCF-R, CCF-G, and CCF-B. The organic pattern COL may fill the division opening O-SP defined in the division pattern SP. The organic pattern COL may serve as a buffer between the display element layer EDL and the light conversion patterns CCF-R, CCF-G, and CCF-B. In an embodiment, the organic pattern COL may serve as a shock absorber and increase the strength of the display panel DP.

The organic pattern COL may include a first organic pattern COL1 disposed in the first division opening O-SP1, and a second organic pattern COL2 disposed in the second division opening O-SP2. The first organic pattern COL1 may fill the first division opening O-SP1 defined in the first division pattern SP1. The second organic pattern COL2 may fill the second division opening O-SP2 defined in the second division pattern SP2.

The organic pattern COL may be disposed (e.g., directly disposed) on an encapsulation layer TFE. An upper surface of the organic pattern COL may contact a lower surface of the light conversion patterns CCF-R, CCF-G, and CCF-B, and a lower surface of the organic pattern COL may contact an upper surface of the encapsulation layer TFE.

The first organic pattern COL1 and the second organic pattern COL2 may each be formed from a filling resin including a polymer resin. For example, the first organic pattern COL1 and the second organic pattern COL2 may each be formed from a filling layer resin including an acryl-based resin or an epoxy-based resin. The first organic pattern COL1 and the second organic pattern COL2 may include a same material or different materials.

Referring to FIG. 3D, a bank well W-OP may be defined in the barrier rib BW. The bank well W-OP may be formed to prevent defects caused by mislanding in a process of patterning multiple light conversion patterns CCF-R, CCF-G, and CCF-B. The bank well W-OP may be a portion receiving materials for forming the light control patterns CCF-R, CCF-G, and CCF-B, which are incorrectly applied in the process of patterning the light control patterns CCF-R, CCF-G, and CCF-B. The bank well W-OP may prevent the incorrectly applied materials for forming the light conversion patterns CCF-R, CCF-G, and CCF-B from remaining on an upper portion of the barrier rib BW and causing defects in the process of forming upper members. The bank well W-OP may be formed by removing a portion of the barrier rib BW. The bank well W-OP may be defined to be spaced apart from the first opening BW-OP in which each of the light conversion patterns CCF-R, CCF-G, and CCF-B is disposed, in a plan view. FIG. 3D shows five bank wells W-OP are defined adjacent to light emitting region groups as an embodiment, but the arrangement of the bank wells W-OP is not limited thereto and may be variously modified.

With an increase in resolution of a display device, a minimum amount of an ink droplet ejection amount that may be ejected by an inkjet nozzle at a time may be greater than a volume of droplets that may fill a space corresponding to one pixel region. Accordingly, the ink droplets ejected by the inkjet nozzle may overflow into pixel regions emitting light of different colors, causing ink color mixing. According to an embodiment of the disclosure, a division pattern surrounding pixel regions representing the same color on a barrier rib confining applied ink droplets for each pixel region is disposed, and accordingly, ink droplets may be effectively prevented from overflowing into pixel regions emitting light of different colors. In addition, the division pattern may surround a pixel group including two or more pixel regions among pixel regions displaying the same color, and accordingly, the inkjet droplets may be received in regions corresponding to two or more pixel regions concurrently to reduce turn around time (TAT) of the inkjet process, leading to improvements in process efficiency.

Referring back to FIG. 3C, at least a portion of the light conversion patterns CCF-R, CCF-G, and CCF-B may alter optical properties of source light. In an embodiment, the first light conversion pattern CCF-R and the second light conversion pattern CCF-G may alter optical properties of source light.

The first light conversion pattern CCF-R and the second light conversion pattern CCF-G may include quantum dots for altering optical properties of source light. The first light conversion pattern CCF-R and the second light conversion pattern CCF-G may include quantum dots that convert the source light into light having a different wavelength. In the first light conversion pattern CCF-R overlapping the first pixel region PXA-R, quantum dots may convert blue light, which is the source light, into red light. In the second light conversion pattern CCF-G overlapping the second pixel region PXA-R, quantum dots may convert blue light, which is the source light, into green light.

Herein, a quantum dot may be a crystal of a semiconductor compound. The quantum dot may emit light of emission wavelengths depending on the size of the crystal. The quantum dot may emit light of various emission wavelengths by regulating an element ratio in the quantum dot compound.

The quantum dot may have a diameter in a range of, for example, about 1 nm to about 10 nm.

The quantum dot may be synthesized through a wet chemical process, a metal organic chemical vapor deposition process, a molecular beam epitaxy process, or a process similar thereto.

The wet chemical process is a method of mixing an organic solvent and a precursor material and growing a quantum dot particle crystal. In case that the crystal grows, the organic solvent naturally serves as a dispersant coordinated to a surface of the quantum dot crystal and may control the growth of the crystal. Therefore, the wet chemical process may be easier than vapor deposition methods such as metal organic chemical vapor deposition (MOCVD) or molecular beam epitaxy (MBE), and may control the growth of quantum dot particles through a low-cost process.

A core of the quantum dot may be selected from a Group II-VI compound, a Group III-V compound, a Group III-VI compound, a Group I-III-VI compound, a Group IV-VI compound, a Group IV element, a Group IV compound, and a combination thereof.

The Group II-VI compound may include a binary compound such as CdSe, CdTe, CdS, ZnS, ZnSe, ZnTe, ZnO, HgS, HgSe, HgTe, MgSe, MgS, and a mixture thereof, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound such as HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The Group II-VI semiconductor compound may further include a Group I metal and/or a Group IV element. The Group I-II-VI compound may include CuSnS or CuZnS, and the Group II-IV-VI compound may include ZnSnS and the like. The Group I-II-IV-VI compound may include a quaternary compound such as Cu₂ZnSnS₂, Cu₂ZnSnS₄, Cu₂ZnSnSe₄, Ag₂ZnSnS₂, and a mixture thereof.

The Group III-VI compound may include a binary compound such as In₂S₃ and In₂Se₃, a ternary compound such as InGaS₃ and InGaSe₃, or any combination thereof.

The Group I-III-VI compound may include a ternary compound such as AgInS, AgInS₂, CuInS, CuInS₂, AgGaS₂, CuGaS₂ CuGaO₂, AgGaO₂, AgAlO₂, or a mixture thereof, or a quaternary compound such as AgInGaS₂ and CuInGaS₂.

The Group III-V compound may include a binary compound such as GaN, GaP, GaAs, GaSb, AlN, AlP, AlAs, AlSb, InN, InP, InAs, InSb, and a mixture thereof, a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group III-V compound may further include a Group II metal. For example, InZnP and the like may be selected as a Group III-II-V compound.

The Group IV-VI compound may include a binary compound such as SnS, SnSe, SnTe, PbS, PbSe, PbTe, and a mixture thereof, a ternary compound such as SnSeS, SnSeTe, SnSTe, PbSeS, PbSeTe, PbSTe, SnPbS, SnPbSe, SnPbTe, and a mixture thereof, and a quaternary compound such as SnPbSSe, SnPbSeTe, SnPbSTe, and a mixture thereof.

Examples of the Group II-IV-V semiconductor compound may be a ternary compound such as ZnSnP, ZnSnP₂, ZnSnAs₂, ZnGeP₂, ZnGeAs₂, CdSnP₂, and CdGeP₂ and a mixture thereof.

The Group IV element may include Si, Ge, and the like. The Group IV compound may be a binary compound such as SiC, SiGe, and the like.

Each element included in the multi-element compound such as the binary compound, ternary compound, and quaternary compound may be present in particles at a uniform concentration or a non-uniform concentration. For example, Formula above indicates the types of elements included in a compound, and element ratios in the compound may be different. For example, AgInGaS₂ may indicate AgInₓGa₁₋ₓS₂ (x is a real number between 0 and 1).

The binary compound, the ternary compound, or the quaternary compound may be present in particles having a uniform concentration distribution, or may be present in the same particles having a partially different concentration distribution. A core/shell structure in which one quantum dot surrounds another quantum dot may be present. The core/shell structure may have a concentration gradient in which the concentration of an element present in the shell becomes lower towards the core.

In some embodiments, a quantum dot may have the core/shell structure including a core having nano-crystals, and a shell surrounding the core, which are described above. The shell of the quantum dot may serve as a protection layer to prevent the chemical deformation of the core so as to keep semiconductor properties, and/or a charging layer to impart electrophoresis properties to the quantum dot. The shell may be a single layer or multiple layers. Examples of the shell of the quantum dot may be a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a ternary compound such as MgAl₂O₄, CoFe₂O₄, NiFe₂O₄, and CoMn₂O₄, but the disclosure is not limited thereto.

The semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like, but the disclosure is not limited thereto.

The quantum dot may have, in an emission wavelength spectrum, a full width of half maximum (FWHM) of less than or equal to about 45. For example, the quantum dot may have, in an emission wavelength spectrum, a full width of half maximum (FWHM) of less than or equal to about 40 nm. For example, the quantum dot may have, in an emission wavelength spectrum, a full width of half maximum (FWHM) of less than or equal to about 30 nm. In this range, the color purity or the color reproducibility may be improved. Light emitted through the quantum dot may be emitted in all directions, and thus a wide viewing angle may be improved.

The form of a quantum dot is not particularly limited as long as it is a form commonly used in the art, and for example, a quantum dot in the form of spherical, pyramidal, multi-arm, or cubic nanoparticles, nanotubes, nanowires, nanofibers, nanoplatelets, and the like may be used.

As the size of the quantum dot or the ratio of elements in the quantum dot compound is regulated, the energy band gap may be accordingly controlled to obtain light of various wavelengths from the quantum dot emission layer. Therefore, by using the quantum dots as described above (using quantum dots of different sizes or having different element ratios in the quantum dot compound), a light emitting element emitting light of various wavelengths may be obtained. For example, the size of the quantum dots or the ratio of elements in the quantum dot compound may be regulated to emit red, green, and/or blue light. The quantum dots may emit white light by combining light of various colors.

In an embodiment, the quantum dots included in the first light conversion pattern CCF-R overlapping the first pixel region PXA-R may have a red emission color. The smaller the particle size of the quantum dot, the shorter wavelength region of light may be emitted. For example, among the quantum dots having the same core, the particle size of the quantum dots that emit green light may be smaller than the particle size of the quantum dots that emit red light. In the quantum dots having the same core, the particle size of the quantum dot emitting blue light may be smaller than the particle size of the quantum dot emitting green light. However, the disclosure is not limited thereto, and even in the quantum dots having the same core, the particle size may be controlled according to a shell forming material and a shell thickness.

In case that the quantum dots have various emission colors such as blue, red, and green, the quantum dots having different emission colors may have different core materials.

Each of the first light conversion pattern CCF-R and the second light conversion pattern CCF-G may further include scatterers. The first light conversion pattern CCF-R may include quantum dots that convert blue light into red light, and scatterers that scatter light. The second light conversion pattern CCF-G may include quantum dots that convert blue light into green light, and scatterers that scatter light.

The scatterers may be inorganic particles. For example, the scatterers may include at least one of TiO₂, ZnO, Al₂O₃, SiO₂, and hollow silica. The scatterers may include at least one of TiO₂, ZnO, Al₂O₃, SiO₂, hollow silica, a mixture of two or more materials selected from TiO₂, ZnO, Al₂O₃, SiO₂, and hollow silica.

The first light conversion pattern CCF-R and the second light conversion pattern CCF-G may include a base resin for dispersing quantum dots and scatterers. The base resin may be a medium in which the quantum dots and the scatterers are dispersed, and may be formed of a resin composition which may be generally referred to as a binder. For example, the base resin may be an acryl-based resin, a urethane-based resin, a silicon-based polymer, an epoxy-based resin, or the like. The base resin may be a transparent resin.

In the embodiment, each of the first light conversion pattern CCF-R and the second light conversion pattern CCF-G may be formed through an inkjet process. In the inkjet process for forming each of the first light conversion pattern CCF-R and the second light conversion pattern CCF-G, a liquid composition may be provided into the opening BW-OP. A composition polymerized through a thermal curing process or a photo-curing process may decrease in volume after being cured, and accordingly, a step may be caused between a lower surface of the barrier rib BW and a lower surface of each of the first and second light conversion patterns CCF-R and CCF-G after the first light conversion pattern CCF-R and the second light conversion pattern CCF-G is each formed through the inkjet process. For example, the lower surface of the barrier rib BW may be higher than the lower surface of each of the first light conversion pattern CCF-R and the second light conversion pattern CCF-G. A difference in height between the lower surface of the barrier rib BW and the lower surface of each of the first light conversion pattern CCF-R and the second light conversion pattern CCF-G may be, for example, in a range of about 2 μm to about 3 μm.

Although not shown, the display device DD according to an embodiment may further include an additional insulating layer disposed on a surface of the light conversion patterns CCF-R, CCF-G, and CCF-B. The additional insulating layer may serve to prevent penetration of moisture and/or oxygen (hereinafter, referred to as ‘moisture/oxygen’) and improve optical properties of an optical structure layer OSL by regulating a refractive index. For example, quantum dots included in the light conversion patterns CCF-R, CCF-G, and CCF-B may be prevented from being exposed to moisture/oxygen. The additional insulating layer may also protect the light conversion patterns CCF-R, CCF-G, and CCF-B from external impact.

The additional insulating layer may cover upper or lower surfaces of the barrier rib BW and the light conversion patterns CCF-R, CCF-G, and CCF-B. For example, the additional insulating layer may include a first additional insulating layer disposed on the upper surface of the light conversion patterns CCF-R, CCF-G, and CCF-B adjacent to the color filters CF-R, CF-G, and CF-B, and a second additional insulating layer disposed on the lower surface of the light conversion patterns CCF-R, CCF-G, and CCF-B adjacent to the display element layer EDL. The second additional insulating layer disposed on the lower surface of the light conversion patterns CCF-R, CCF-G, and CCF-B may be disposed to follow the step between the barrier rib BW and the light conversion patterns CCF-R, CCF-G, and CCF-B. The second additional insulating layer may be disposed between the organic pattern COL and the light conversion patterns CCF-R, CCF-G, and CCF-B. As used herein, the “upper surface” may be a surface placed on an upper portion with respect to the third direction DR3, and the “lower surface” may be a surface placed on a lower portion with respect to the third direction DR3.

The additional insulating layer may include an inorganic material. In the display device DD according to an embodiment, the additional insulating layer may include at least one of silicon oxynitride (SiON), silicon oxide (SiOₓ), and silicon nitride (SiNₓ).

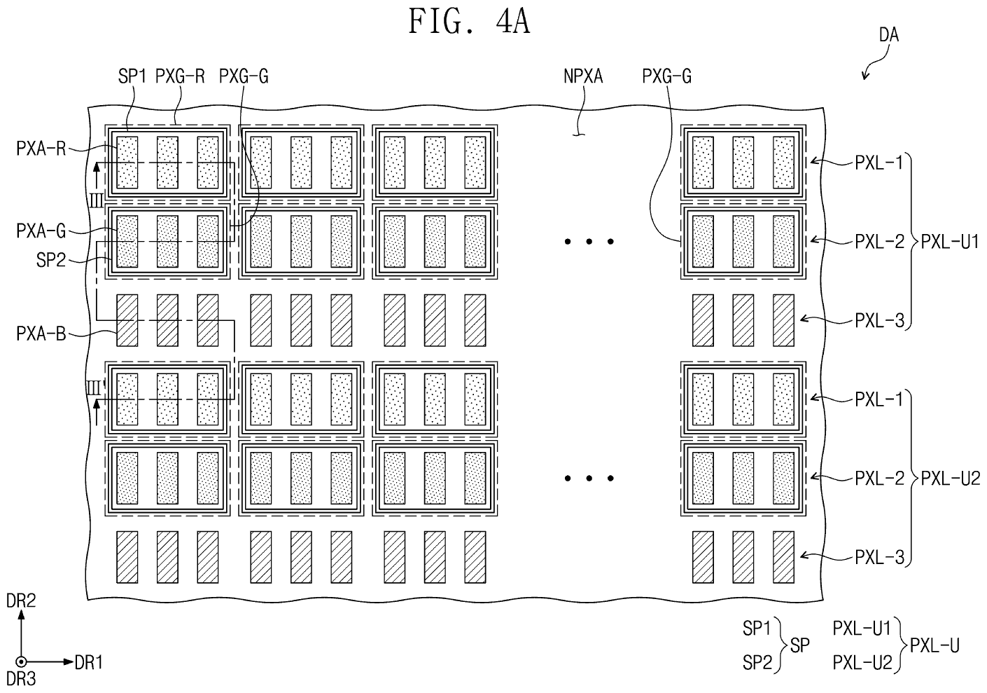

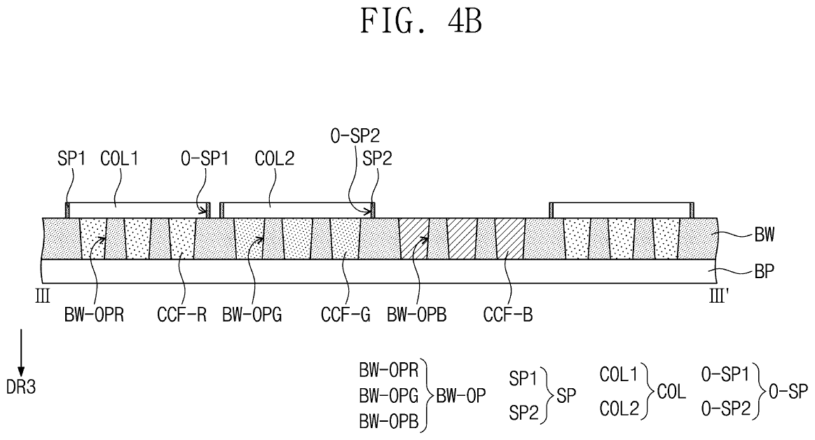

FIG. 4A is an enlarged plan view of a display region DA according to another embodiment of the disclosure. FIG. 4B is a schematic cross-sectional view corresponding to III-III′ of FIG. 4A.

The pixel arrangement of the pixel regions PXA-R, PXA-G, and PXA-B included in the display region DA shown in FIG. 4A may be different from the pixel arrangement of the pixel regions PXA-R, PXA-G, and PXA-B included in the display region DA shown in FIG. 3A.

Referring to FIG. 4A, the display region DA may include multiple pixel regions PXA-R, PXA-G, and PXA-B, and a peripheral region NPXA adjacent to the pixel regions PXA-R, PXA-G, and PXA-B. The peripheral region NPXA may set a boundary between the first to third pixel regions PXA-R, PXA-G, and PXA-B, and prevent the first to third pixel regions PXA-R, PXA-G, and PXA-B from being color-mixed. Each of the first to third pixel regions PXA-R, PXA-G, and PXA-B may be included in multiple pixel rows PXL-1, PXL-2, and PXA-3 extending in the first direction DR1.

Each of the first to third pixel regions PXA-R, PXA-G, and PXA-B may be disposed in different rows. FIG. 4A shows that areas of the pixel regions PXA-R, PXA-G, and PXA-B are all similar in size in a plan view, but the disclosure is not limited thereto, and the areas of the pixel regions PXA-R, PXA-G and PXA-B may be different in size from each other according to wavelength range of emitted light. The areas of the pixel regions PXA-R, PXA-G, and PXA-B may be areas in a plan view defined by the first direction DR1 and the second direction DR2.

FIG. 4A shows that the first pixel region PXA-R, the second pixel region PXA-G, and the third pixel region PXA-B have a substantially square shape in a plan view, but the disclosure is not limited thereto. In a plan view, the first to third pixel regions PXA-R, PXA-G, and PXA-B may have other polygonal shapes such as a rhombus or a pentagon.

In the embodiment, the pixel rows PXL-1, PXL-2, and PXL-3 may be divided into three groups. The pixel rows PXL-1, PXL-2, and PXL-3 may include first pixel rows PXL-1, second pixel rows PXL-2, and third pixel rows PXL-3, which are spaced apart in the second direction DR2. In the second direction DR2, the first pixel rows PXL-1, the second pixel rows PXL-2, and the third pixel rows PXL-3 may be alternately disposed.

Each of the first pixel rows PXL-1 may include first pixel regions PXA-R arranged in the first direction DR1. Each of the second pixel rows PXL-2 may include second pixel regions PXA-G arranged in the first direction DR1. Each of the third pixel rows PXL-3 may include third pixel regions PXA-B arranged in the first direction DR1.

Among the pixel regions PXA-R, PXA-G, and PXA-B, one first pixel region PXA-R, one second pixel region PXA-G, and one third pixel region PXA-B, which are arranged in the second direction DR2 may form one unit pixel. One first pixel row PXL-1, one second pixel row PXL-2, and one third pixel row PXL-3 may define one unit pixel row PXL-U. The unit pixel rows PXL-U may be arranged in the second direction DR2. In one unit pixel row PXL-U, multiple unit pixels may be arranged in the first direction DR1. FIG. 4A shows a first unit pixel row PXL-U1 and a second unit pixel row PXL-U2 as an embodiment.

Referring to FIGS. 4A to 4D, the display device DD according to an embodiment may include a division pattern SP overlapping the peripheral region NPXA and surrounding a corresponding pixel region among the pixel regions PXA-R, PXA-G, and PXA-B in a plan view. In a plan view defined by the first direction DR1 and the second direction DR2, the division pattern SP may surround each of the first pixel region PXA-R and the second pixel region PXA-G. The division pattern SP may be disposed on the barrier rib BW to surround each of the first and second pixel regions PXA-R and PXA-G in a plan view, and thus, the first and second pixel regions PXA-R and PXA-G may be separated from each other.

The first and second pixel regions PXA-R and PXA-G included in the first pixel row PXL-1 and the second pixel row PXL-2 may be divided into multiple pixel region groups. The first and second pixel regions PXA-R and PXA-G may be divided into the pixel region groups by the division pattern SP.

The first pixel row PXL-1 may include multiple first pixel region groups PXG-R including n first pixel regions PXA-R. In the first pixel row PXL-1, each of the first pixel region groups PXG-R may include n first pixel regions PXA-R. n may be an integer of 2 or greater. For example, n may be 2. For example, the first pixel row PXL-1 may include first pixel region groups PXG-R each including two or more first pixel regions PXA-R. FIG. 4A shows an embodiment in which n is 3, but the disclosure is not limited thereto.

The second pixel row PXL-2 may include multiple second pixel region groups PXG-G including m second pixel regions PXA-G. Each of the second pixel region groups PXG-G may include m second pixel regions PXA-G. m may be an integer of 2 or greater. For example, m may be 2. For example, the second pixel row PXL-2 may include second pixel region groups PXG-G each including two or more second pixel regions PXA-G. FIG. 4A shows an embodiment in which m is 3, but the disclosure is not limited thereto.

As shown in FIG. 4A, the division pattern SP may surround the first pixel region PXA-R disposed in the first pixel row PXL-1, and may surround the second pixel region PXA-G disposed in the second pixel row PXL-2. The division pattern SP may include a first division pattern SP1 surrounding the first pixel region PXA-R disposed in the first pixel row PXL-1, and a second division pattern SP2 surrounding the second pixel region PXA-G disposed in the second pixel row PXL-2.

The division pattern SP may surround each of the first pixel region group PXG-R and the second pixel region group PXG-G. The division pattern SP may surround the first pixel region group PXG-R including n first pixel regions PXA-R in the first pixel row PXL-1, and the second pixel region group PXG-G including m second pixel regions PXA-G in the second pixel row PXL-2. The division pattern SP may completely surround each of the first pixel region group PXG-R and the second pixel region group PXG-G in a plan view defined by the first direction DR1 and the second direction DR2.

The third pixel regions PXA-B disposed in the third pixel row PXL-3 may not be surrounded by the division pattern SP. As described above with reference to FIG. 3A, each of the first light conversion pattern CCF-R and the second light conversion pattern CCF-G may be formed through an inkjet process, and the transmission pattern CCF-B may be formed through a photolithography process. In case that the transmission pattern CCF-B corresponding to the third pixel region PXA-B is formed through a photolithography process, the division pattern SP may not be disposed on the barrier rib BW adjacent to the third pixel regions PXA-B.

As each of the first and second pixel regions PXA-R and PXA-G is divided into first and second pixel region groups PXG-R and PXG-G by the division pattern SP, ink color mixing between neighboring pixels during the inkjet process may be prevented in the forming of the light conversion patterns CCF-R and CCF-G. An ink composition for forming the first light conversion pattern CCF-R may be concurrently dripped onto portions corresponding to n first pixel regions PXA-R, and an ink composition for forming the second light conversion pattern CCF-G may be concurrently dripped onto portion corresponding to m second pixel regions PXA-G, and thus the number of processes may be reduced compared to a method of dripping an ink composition onto individual pixel regions. Accordingly, the inkjet process for forming the light conversion patterns CCF-R and CCF-G may be provided with reduced turnaround time (TAT) to improve process efficiency.

In an embodiment, the division pattern SP and the transmission pattern CCF-B may be formed through a same process. The division pattern SP and the transmission pattern CCF-B may be formed through a photolithography process. During the light conversion patterns CCF-R, CCF-G, and CCF-B are formed, the division pattern SP and the transmission pattern CCF-B may be formed using a photolithography process, and the first light conversion pattern CCF-R and the second light conversion pattern CCF-G may be formed using an inkjet process.

The division pattern SP and the transmission pattern CCF-B corresponding to the third pixel region PXA-B may include a same material. As the division pattern SP is formed through the same process as the transmission pattern CCF-B, the division pattern SP and the transmission pattern CCF-B may include a same material. For example, the division pattern SP may include a base resin. The division pattern SP may further include scattering particles mixed with the base resin. The scattering particles may be titanium oxide (TiO₂) or silica-based nanoparticles.

Referring to FIG. 4B, in the division pattern SP, a division opening O-SP overlapping a corresponding pixel region among the first pixel region PXA-R, the second pixel region PXA-G, and the third pixel region PXA-B in a plan view may be defined. As shown in FIG. 4B, in the division pattern SP, a division opening O-SP overlapping each of the first pixel region PXA-R included in the first pixel row PXL-1 and the second pixel region PXA-G included in the second pixel row PXL-2 may be defined. The division opening O-SP may overlap the first pixel region PXA-R included in the first pixel region group PXG-R and the second pixel region PXA-G included in the second pixel region group PXG-G in a plan view.

In a plan view defined by the first direction DR1 and the second direction DR2, an area of the division opening O-SP may be greater than areas of each of the first openings BW-OP defined in the barrier rib BW. For example, a planar area of the division opening O-SP may be greater than a planar area of each of (1-1)-th openings BW-OPR defined to correspond to the first pixel region PXA-R, and (1-2)-th openings BW-OPG defined to correspond to the second pixel region PXA-G.

An organic pattern COL may be disposed in the division opening O-SP defined in the division pattern SP. The organic pattern COL may fill the division opening O-SP. In an embodiment shown in FIGS. 4A and 4B, an organic pattern COL1 disposed in the division opening O-SP overlapping the first pixel region PXA-R included in the first pixel row PXL-1 may be referred to as a first organic pattern, and an organic pattern COL2 disposed in the division opening O-SP overlapping the second pixel region PXA-G included in the second pixel row PXL-2 may be referred to as a second organic pattern.

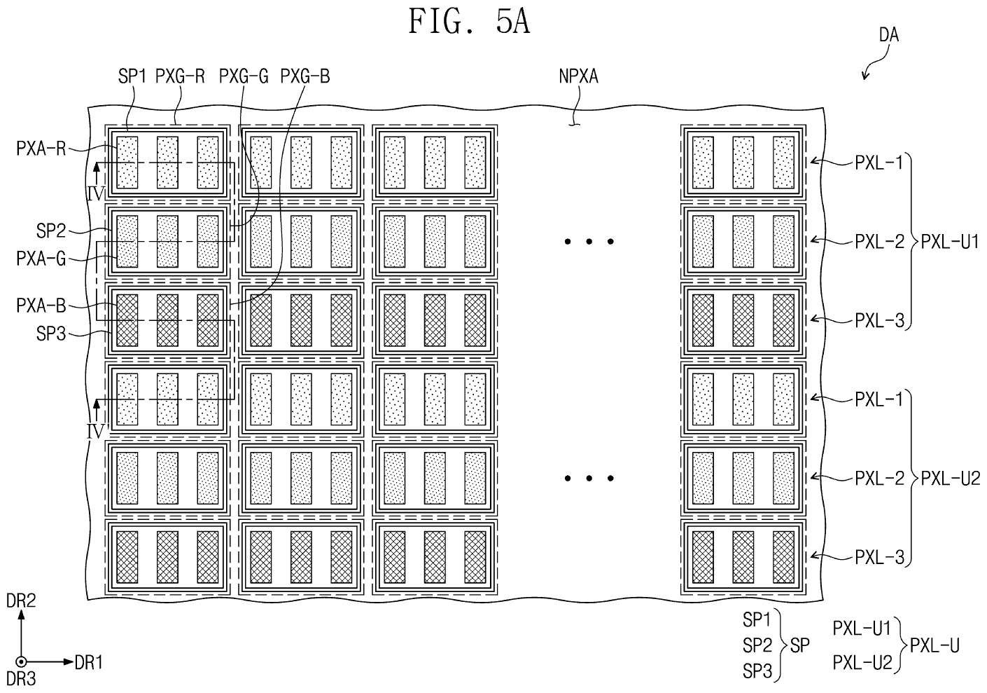

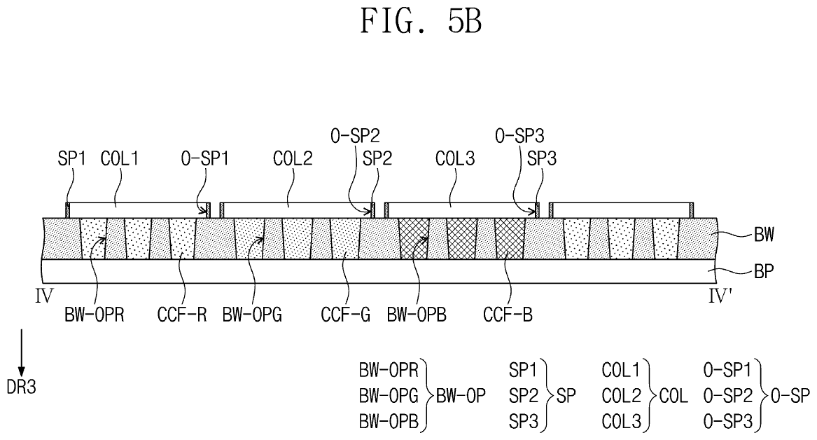

FIG. 5A is an enlarged plan view of a display region DA according to another embodiment of the disclosure. FIG. 5B is a schematic cross-sectional view corresponding to IV-IV′ of FIG. 5A.

Compared to the division pattern SP shown in FIG. 4A, a division pattern SP shown in FIG. 5A may further include a third division pattern surrounding a third light emitting region PXA-B included in a third pixel row PXL-3.

Referring to FIGS. 5A and 5B, the division pattern SP may be disposed on the barrier rib BW to overlap the peripheral region NPXA, and may surround a corresponding pixel region among multiple pixel regions PXA-R, PXA-G, and PXA-B in a plan view. In a plan view, the division pattern SP may surround each of the first pixel region PXA-R, the second pixel region PXA-G, and the third pixel region PXA-B. The division pattern SP may surround each of the first to third pixel regions PXA-R, PXA-G, and PXA-B in a plan view, and thus, the first to third pixel regions PXA-R, PXA-G, and PXA-B may be separated from each other.

The first to third pixel regions PXA-R, PXA-G, and PXA-B included in the first pixel row PXL-1, the second pixel row PXL-2, and the third pixel row PXL-3 may be divided into multiple pixel region groups. The first to third pixel regions PXA-R, PXA-G, and PXA-B may each be divided into multiple pixel region groups by the division pattern SP.

The first to third pixel rows PXL-1, PXL-2, and PXL-3 may include first to third pixel region groups PXG-R, PXG-G and PXG-B each including two or more first to third pixel regions PXA-R, PXA-G and PXA-B. The first pixel row PXL-1 may include multiple first pixel region groups PXG-R including n first pixel regions PXA-R. The second pixel row PXL-2 may include multiple second pixel region groups PXG-G including m second pixel regions PXA-G. The third pixel row PXL-3 may include multiple third pixel region groups PXG-B including z third pixel regions PXA-B. Each of the first to third pixel region groups PXG-R, PXG-G, and PXG-B may be surrounded by the division pattern SP. n, m, and z may each be an integer of 2 or greater. n, m, and z may each be the same or different. FIG. 5A shows an embodiment in which n, m, and z are each 3, but the disclosure is not limited thereto.

The division pattern SP may surround each of the first pixel region group PXG-R, the second pixel region group PXG-G, and the third pixel region group PXG-B. The division pattern SP may completely surround each of the first pixel region group PXG-R, the second pixel region group PXG-G, and the third pixel region group PXG-B in a plan view defined by the first direction DR1 and the second direction DR2. The division pattern SP may include a first division pattern SP1 surrounding the first pixel region PXA-R disposed in the first pixel row PXL-1, a second division pattern SP2 surrounding the second pixel region PXA-G disposed in the second pixel row PXL-2, and a third division pattern SP3 surrounding the third pixel region PXA-B disposed in the third pixel row PXL-3.

Unlike the transmission pattern CCF-B shown in FIG. 4A, a transmission pattern CCF-B shown in FIG. 5A may be formed through an inkjet process in the same manner as the first light conversion pattern CCF-R and the second light conversion pattern CCF-G. As the first to third pixel regions PXA-R, PXA-G, and PXA-B are separated by the division pattern SP, ink color mixing between neighboring pixels during the inkjet process may be prevented in the forming of the light conversion patterns CCF-R, CCF-G, and CCF-B. An ink composition for forming the first light conversion pattern CCF-R may be concurrently dripped onto portions corresponding to n first pixel regions PXA-R, and ink composition for forming the second light conversion pattern CCF-G may be concurrently dripped onto portions corresponding to m second pixel regions PXA-G, and an ink composition for forming the transmission pattern CCF-B may be concurrently dripped onto portions corresponding to z third pixel regions PXA-B. Accordingly, the number of processes may be reduced compared to a method of dripping an ink composition onto individual pixel regions, and thus the inkjet process for forming the light conversion patterns CCF-R, CCF-G, and CCF-B may be provided with reduced turn around time (TAT) to improve process efficiency.

In an embodiment, the division pattern SP may be formed through a photolithography process. The division pattern SP may be formed using a photolithography process, and the light conversion patterns CCF-R, CCF-G, and CCF-B may be formed using an inkjet process.

Referring to FIG. 5B, a division opening O-SP may be defined in the division pattern SP. As shown in FIG. 5B, in the division pattern SP, a division opening O-SP overlapping each of the first pixel region PXA-R included in the first pixel row PXL-1, the second pixel region PXA-G included in the second pixel row PXL-2, and the third pixel region PXA-B included in the third pixel row PXL-3 may be defined. The division opening O-SP may include a first division opening O-SP1 defined in a first division pattern SP1, a second division opening O-SP2 defined in a second division pattern SP2, and a third division opening O-SP3 defined in a third division pattern SP3.

In a plan view, an area of the division opening O-SP may be greater than an area of each of the first openings BW-OP (FIG. 3C) defined in the barrier rib BW. For example, a planar area of the division opening O-SP may be greater than a planar area of each of (1-1)-th openings BW-OPR defined to correspond to the first pixel region PXA-R, (1-2)-th openings BW-OPG defined to correspond to the second pixel region PXA-G, and (1-3)-th openings BW-OPB defined to correspond to the third pixel region PXA-B.

An organic pattern COL may be disposed in the division opening O-SP defined in the division pattern SP. The organic pattern COL may fill the division opening O-SP. In an embodiment shown in FIGS. 5A and 5B, an organic pattern COL1 disposed in the division opening O-SP1 overlapping the first pixel region PXA-R may be referred to as a first organic pattern, an organic pattern COL2 disposed in the division opening O-SP2 overlapping the second pixel region PXA-G may be referred to as a second organic pattern, and an organic pattern COL3 disposed in the division opening O-SP3 overlapping the third pixel region PXA-B may be referred to as a third organic pattern.

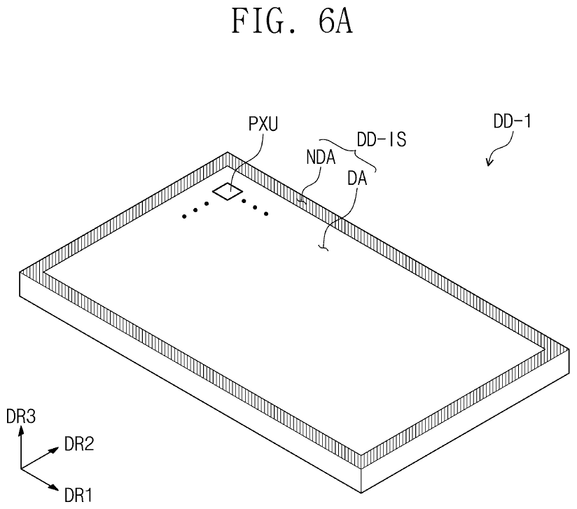

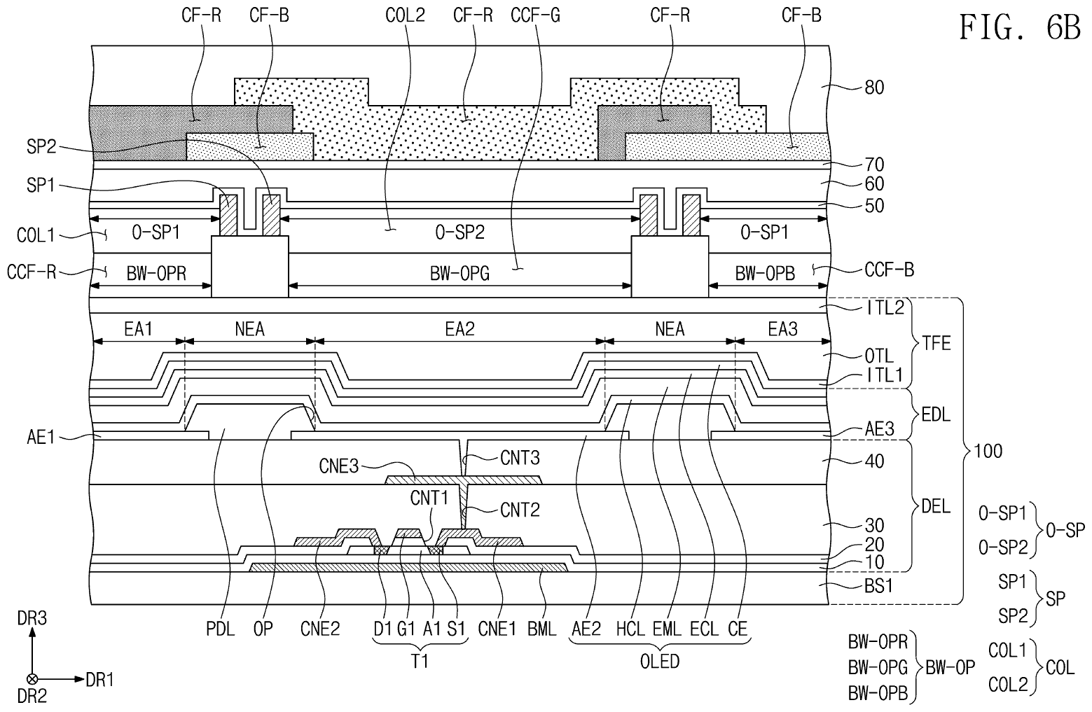

FIG. 6A is a perspective view of a display device DD-1 according to an embodiment of the disclosure. FIG. 6B is a schematic cross-sectional view of a display device DD-1 according to an embodiment of the disclosure. Hereinafter, in describing a display device according to an embodiment of the disclosure with reference to FIGS. 6A and 6B, the same reference numerals are given to components that are the same as the components described above, and detailed descriptions thereof will not be given.

Unlike the display device DD described with reference to FIGS. 1A to 5B, the display device DD according to an embodiment of the disclosure may include one base layer BS1. In the manufacturing process, a bonding process between the display panel 100 and the light conversion panel 200 may be omitted, and structures may be sequentially formed on the base layer BS1.

According to FIGS. 6A and 6B, a display device DD-1 may include the same display panel 100 of FIG. 3C. A barrier rib BW may be disposed on an encapsulation layer TFE. The barrier rib BW may be disposed (e.g., directly disposed) on the encapsulation layer TFE. Unlike the display device DD shown in FIG. 3C, in the display device DD-1 according to an embodiment, components such as the barrier rib BW, a first light conversion pattern CCF-R, a second light conversion pattern CCF-G, and a transmission pattern SP may be disposed on an upper surface of the encapsulation layer TFE as a reference plane.

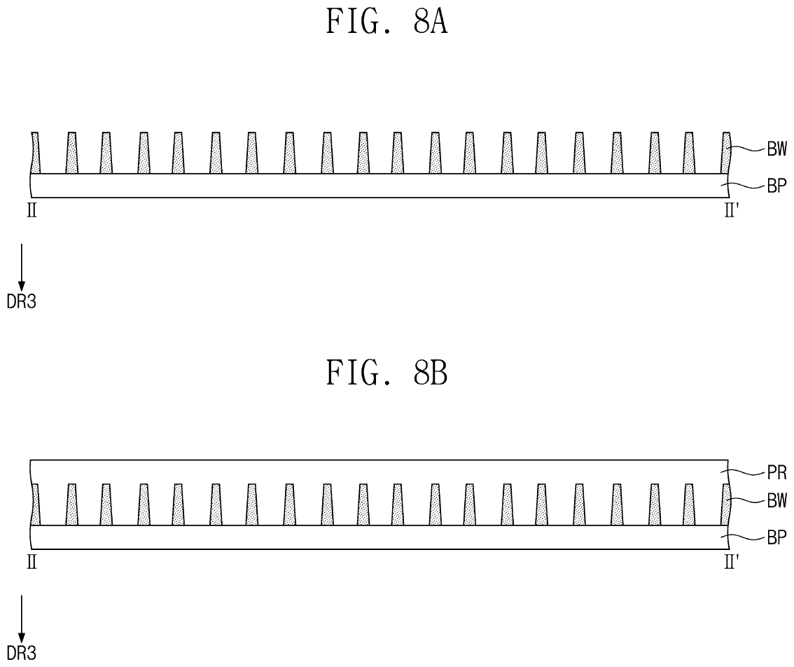

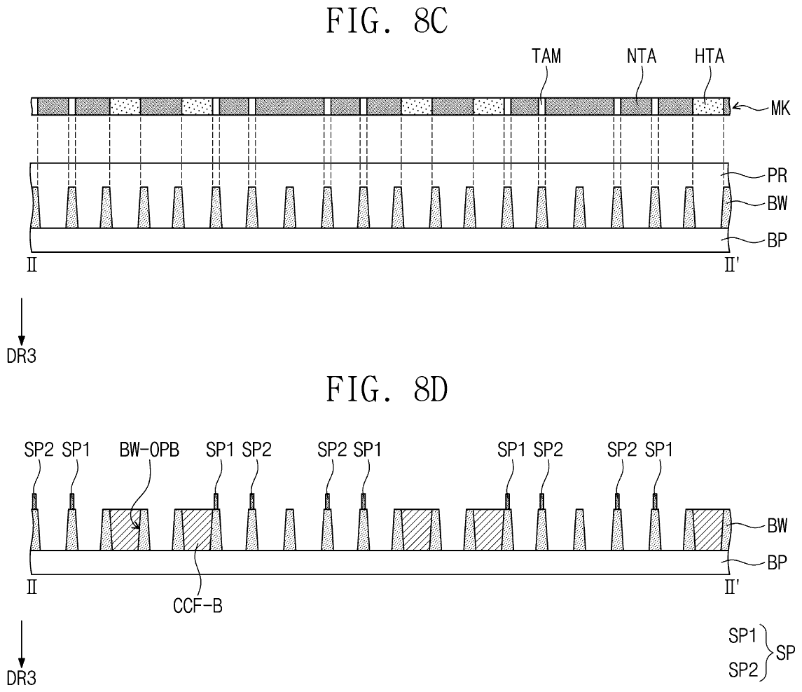

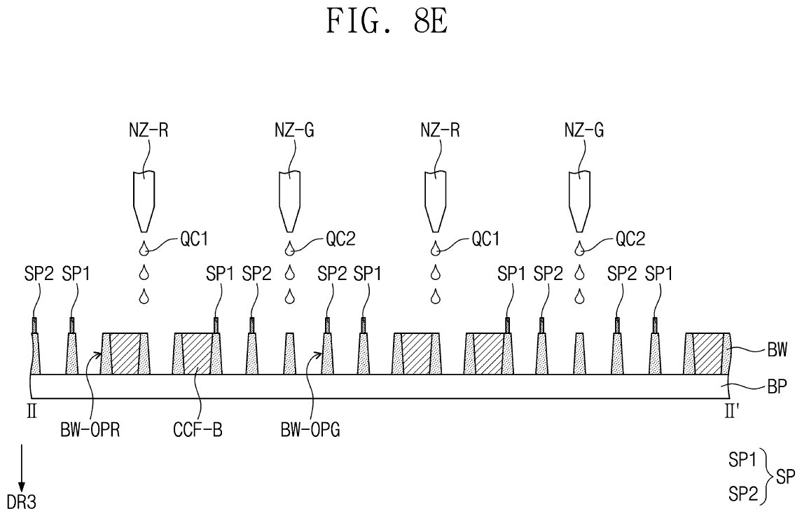

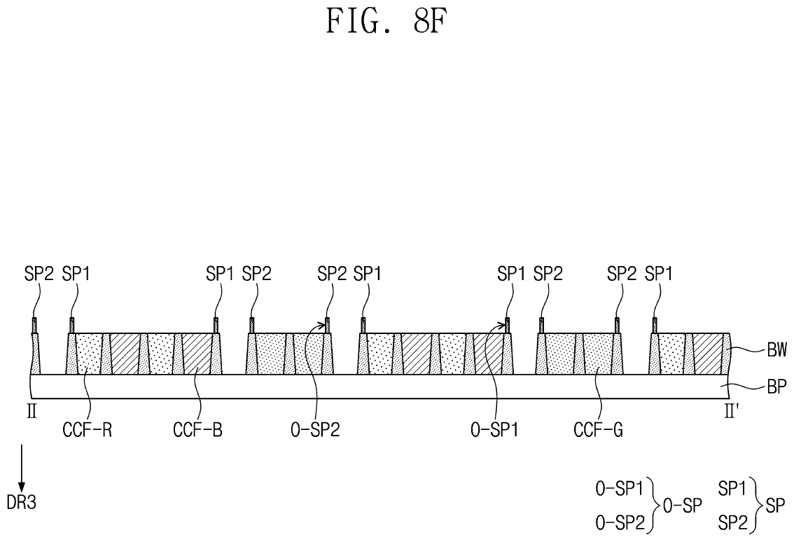

The first light conversion pattern CCF-R, the second light conversion pattern CCF-G, and the transmission pattern CCF-B may each be disposed in an opening BW-OP of the barrier rib BW. The division pattern SP may be disposed on the barrier rib BW. The division pattern SP may be disposed (e.g., directly disposed) on the barrier rib BW. A division opening O-SP corresponding to a corresponding pixel region among multiple pixel regions PXA-R, PXA-G, and PXA-B may be defined in the division pattern SP. An organic pattern COL may be disposed inside the division opening O-SP. In an embodiment shown in FIG. 8B, the organic pattern COL may be omitted.

A fifth insulating layer 50 may be disposed on the division pattern SP and the organic pattern COL. The fifth insulating layer 50 may cover the division pattern SP and the organic pattern COL. The fifth insulating layer 50 may cover a portion of the barrier rib BW. A portion of an upper surface of the barrier rib BW, which is not in contact with the division pattern SP may be covered by the fifth insulating layer 50. In case that the organic pattern COL is omitted, the fifth insulating layer 50 may cover the division pattern SP, the first light conversion pattern CCF-R, the second light conversion pattern CCF-G, and the transmission pattern CCF-B. The fifth insulating layer 50 may be an inorganic film.

A sixth insulating layer 60 may be disposed on the fifth insulating layer 50. The sixth insulating layer 60 may have a lower refractive index than the fifth insulating layer 50. The sixth insulating layer 60 may have a refractive index in a range of about 1.1 to about 1.5. The refractive index of the sixth insulating layer 60 may be controlled by the proportion of hollow inorganic particles and/or voids included in the sixth insulating layer 60. The sixth insulating layer 60 may provide source light and transmit light more vertically.

A seventh insulating layer 70 may be disposed on the sixth insulating layer 60. The seventh insulating layer 70 may be an inorganic layer that seals lower structures. The seventh insulating layer 70 may be omitted.

A first color filter CF-R, a second color filter CF-G, and a third color filter CF-B may be disposed on the seventh insulating layer 70. An eighth insulating layer 80 may be disposed on the first color filter CF-R, the second color filter CF-G, and the third color filter CF-B, and the eighth insulating layer 80 may cover the first color filter CF-R, the second color filter CF-G, and the third color filter CF-B and provide a flat surface. The eighth insulating layer 80 may be an organic film.

Although not separately shown, a planar pixel arrangement structure of the pixel regions PXA-R, PXA-G, and PXA-B and an arrangement structure of the division pattern SP may be the same as one of the embodiments described with reference to FIGS. 3A to 5B.

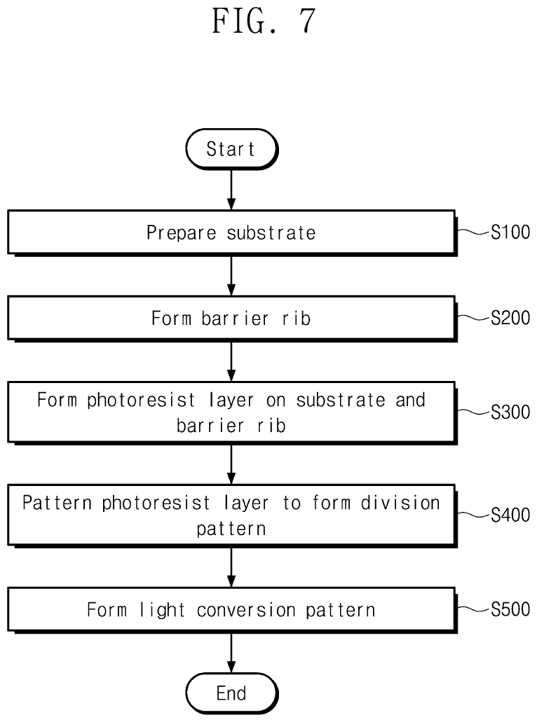

FIG. 7 is a flowchart showing a method for manufacturing a display device according to an embodiment of the disclosure. FIGS. 8A to 8F are schematic cross-sectional views showing processes in a method for manufacturing a display device according to an embodiment of the disclosure. FIGS. 8A to 8F schematically show steps of forming a barrier rib BW and light conversion patterns CCF-R, CCF-G, and CCF-B at a portion corresponding to the cross-section II-II′ of FIG. 3A. Hereinafter, in describing the method for manufacturing a transparent electrode according to an embodiment with reference to FIGS. 7, and 8A to 8F, the same reference numerals are given to components that are the same as the components described above, and detailed descriptions thereof will not be given.

Referring to FIG. 7, the method for manufacturing a display device according to an embodiment may include preparing a substrate (S100), forming a barrier rib (S200), forming a photoresist layer on the substrate and the barrier rib (S300), patterning the photoresist layer to form a division pattern (S400), and forming a light conversion pattern (S500).

The method for manufacturing a display device according to an embodiment of the disclosure may include preparing a substrate (S100). A substrate BP may provide a reference plane on which a barrier rib BW is formed. The substrate BP may include a functional layer included in the light conversion panel 200 shown in FIG. 3C, and the barrier rib BW may be formed on a reference plane provided by a functional layer included in the light conversion panel 200, for example, a second insulating layer 200-2. However, the substrate BP is not limited thereto, and the substrate BP may include the display panel 100 shown in FIG. 6B and the like, and the barrier rib BW may be formed on a reference plane provided by a functional layer included in the display panel 100, for example, a first base layer BS1, a circuit layer DEL, or a display element layer EDL. For example, the substrate BP may include a functional layer included in the display panel 100 shown in FIG. 6B, and the barrier rib BW may be formed on a reference plane provided by a functional layer included in the display panel 100, for example, an encapsulation layer TFE.

Referring to FIGS. 3A to 3D and FIG. 8A together, the barrier rib BW may be formed on a surface of the substrate BP. Multiple pixel regions may be defined on the substrate BP. The pixel regions defined on the substrate BP may correspond to the first to third pixel regions PXA-R, PXA-G, and PXA-B described with reference to FIGS. 3A to 3D. In the forming of the barrier rib BW, first openings BW-OP corresponding to the pixel regions PXA-R, PXA-G, and PXA-B may be formed. For example, in the forming of the barrier rib BW, a (1-1)-th opening BW-OPR corresponding to the first pixel region PXA-R, a (1-2)-th opening BW-OPG corresponding to the second pixel region PXA-G, and a (1-3)-th opening BW-OPB corresponding to the third pixel region PXA-B may be formed in the barrier rib BW.

FIG. 8B schematically illustrates a forming of a photoresist layer on the substrate and the barrier rib (S300). Referring to FIG. 8B, a photoresist layer PR may be formed on the substrate BP and the barrier rib BW. The photoresist layer PR may be formed by coating the substrate BP and the barrier rib BW with a photoresist composition. The photoresist composition may include a photosensitive material. Physical properties of the photoresist layer PR formed of the photoresist composition containing a photosensitive material may vary with/without light irradiation.

Referring to FIGS. 3A to 3D and 8B together, the photoresist layer PR may be formed to overlap the pixel regions PXA-R, PXA-G, and PXA-B and a peripheral region NPXA adjacent to the pixel regions PXA-R, PXA-G, and PXA-B in a plan view. The photoresist layer PR may be disposed in each of first openings BW-OP. The photoresist layer PR may be provided to have a uniform thickness on the barrier rib BW. The thickness of the photoresist layer PR provided on the substrate BP and the barrier rib BW may indicate the distance from an upper surface of the substrate BP to an upper surface of the photoresist layer PR. The thickness of the photoresist layer PR may be regulated in consideration of a thickness of a division pattern SP, which will be formed later.

FIG. 8C schematically illustrates a patterning of a photoresist layer to form a division pattern (S400). As shown in FIG. 8C, the photoresist layer may be patterned using a photolithography process. To pattern the photoresist layer PR, a mask MK may be provided onto the photoresist layer PR. The mask MK may include a transmission portion TAM, a semi-transmission portion HTA, and a light blocking portion NTA. Positions of the transmission portion TAM, the semi-transmission portion HTA, and the light blocking portion NTA within the mask MK may vary depending on a pattern to be formed from the photoresist layer PR, using the mask MK. The mask MK may be a half tone mask including regions having different light transmittances within the mask MK.

The transmission portion TAM may be a region through which emitted light is transmitted through the mask MK. The light blocking portion NTA may be a region in which emitted light is blocked by the mask MK. The semi-transmission portion HTA may be a region having a lower light transmittance than the transmission portion TAM and a higher light transmittance than the light blocking portion NTA. The patterning shape of the photoresist layer PR may vary depending on the extent of light transmission through the mask MK to the photoresist layer PR. Although not shown, the photoresist layer PR may be divided into a first region, a second region, and a third region respectively corresponding to the transmission portion TAM, the semi-transmission portion HTA, and the light blocking portion NTA of the mask MK.

After the photoresist layer PR exposed through the mask MK is developed, as shown in FIG. 8D, the first region of the photoresist layer PR provided with light transmitted through the transmission portion TAM of the mask MK may remain without being removed. The first region of the photoresist layer PR overlapping the transmission portion TAM may form the division patterns SP1 and SP2 shown in FIG. 8D.

An amount of light emitted to the second region of the photoresist layer PR overlapping the semi-transmission portion HTA of the mask MK may be less than an amount of light emitted to the first region of the photoresist layer PR overlapping the transmission portion TAM. After the developing of the photoresist layer PR exposed through the mask MK, a portion of the second region of the photoresist layer PR overlapping the semi-transmission portion HTA may be removed in a thickness direction. A portion of the photoresist layer PR overlapping the semi-transmission portion HTA of the mask MK may be removed to form the transmission pattern CCF-B shown in FIG. 8D. The transmission pattern CCF-B may have a smaller thickness than the division pattern SP. An upper surface of the transmission pattern CCF-B may be formed to be lower than an upper surface of the division pattern SP.

The third region of the photoresist layer PR overlapping the light blocking portion NTA of the mask MK may be blocked from light irradiation by the light blocking portion NTA. After the developing of the photoresist layer PR exposed through the mask MK, the third region of the photoresist layer PR to which light is blocked by the light blocking portion NTA of the mask MK and thus is not provided may be completely removed to expose a surface of the substrate BP.

In the descriptions of FIGS. 8C and 8D, the case of using a negative photoresist in which an unexposed portion of the photoresist layer is removed is presented as an embodiment, but the disclosure is not limited thereto, and in an embodiment, a positive photoresist in which an exposed portion of a photoresist film is removed may also be used.

Referring to FIGS. 3A to 3D, 8C, and 8D together, the photoresist layer PR may be patterned using the mask MK to form the division pattern SP and the transmission pattern CCF-B. Through the patterning of the photoresist layer PR, the division pattern SP in which division openings O-SP overlapping each of the first pixel region PXA-R and the second pixel region PXA-G is defined may be formed. Through the patterning of the photoresist layer PR, a first division pattern SP1 surrounding the first pixel region PXA-R and the third pixel region PXA-B included in the first pixel rows PXL-1, and a second division pattern SP2 surrounding the second pixel region PXA-G included in the second pixel rows PXL-2 may be formed. A first division opening O-SP1 overlapping the first pixel region PXA-R and the third pixel region PXA-B may be defined in the first division pattern SP1, and a second division opening O-SP2 overlapping the second pixel region PXA-G may be defined in the second division pattern SP2. Through the patterning of the photoresist layer PR, the transmission pattern CCF-B corresponding to the third pixel region PXA-B may be formed.

FIG. 8E schematically illustrates a forming of a light conversion pattern (S500). Referring to FIGS. 3A to 3D and 8E, a first composition QC1 may be provided inside the (1-1)-th opening BW-OPR, and a second composition QC2 may be provided inside the (1-2)-th opening BW-OPG. The first composition QC1 may include red quantum dots, and the second composition QC2 may include green quantum dots. The division pattern SP may prevent the first and second compositions QC1 and QC2 from overflowing into adjacent pixel regions displaying different colors. The first division pattern SP1 may prevent the first composition QC1 from overflowing into the adjacent (1-2)-th opening BW-OPG. The second division pattern SP2 may prevent the second composition QC2 from overflowing into the adjacent (1-1)-th opening BW-OPR.

Referring to FIG. 8E, the first composition QC1 and the second composition QC2 may be provided using an inkjet process. An inkjet head may include a first nozzle group and a second nozzle group. The first nozzle group includes multiple first nozzles NZ-R providing the first composition QC1. The second nozzle group includes multiple second nozzles NZ-G providing the second composition QC2.

Referring to FIGS. 3A and 8E together, the first nozzle group and the second nozzle group may provide the first composition QC1 and the second composition QC2 to corresponding one of the first pixel region group divided by the first division pattern SP1 and the second pixel region group divided by the second division pattern SP2. The first nozzles NZ-R included in the first nozzle group may provide the first composition QC1 to each first pixel region group divided by the first division pattern SP1. The second nozzles NZ-G included in the second nozzle group may provide the second composition QC2 to each second pixel region group divided by the second division pattern SP2. As the first pixel region PXA-R and the second pixel region PXA-G are separated by the division pattern SP, the first composition QC1 and the second composition QC2 may not be mixed in an inkjet process.

According to the embodiment, as described with reference to FIGS. 3A to 3D, the first division pattern SP1 may surround the first light emitting region group including two or more first pixel regions PXA-R, and accordingly, the first composition QC1 may be concurrently provided in the (1-1)-th openings BW-OPR corresponding to two or more first pixel regions PXA-R. The second division pattern SP2 may surround the second light emitting region group including two or more second pixel regions PXA-G, and accordingly, the second composition QC2 may be concurrently provided in the (1-2)-th openings BW-OPG corresponding to two or more second pixel regions PXA-G. Accordingly, the inkjet process may be provided with reduced turn around time (TAT) to improve process efficiency.

Referring to FIGS. 3A to 3D, 8E and 8F, the first composition QC and the second composition QC2 provided in each of the (1-1)-th opening BW-OPR and the (1-2)-th opening BW-OPG may be cured. As a result, the first light conversion pattern CCF-R and the second light conversion pattern CCF-G may be formed. Although not separately shown, the method for manufacturing a display device according to an embodiment may further include forming the organic pattern COL (FIG. 3D) filling the division openings O-SP defined in the divided pattern SP.

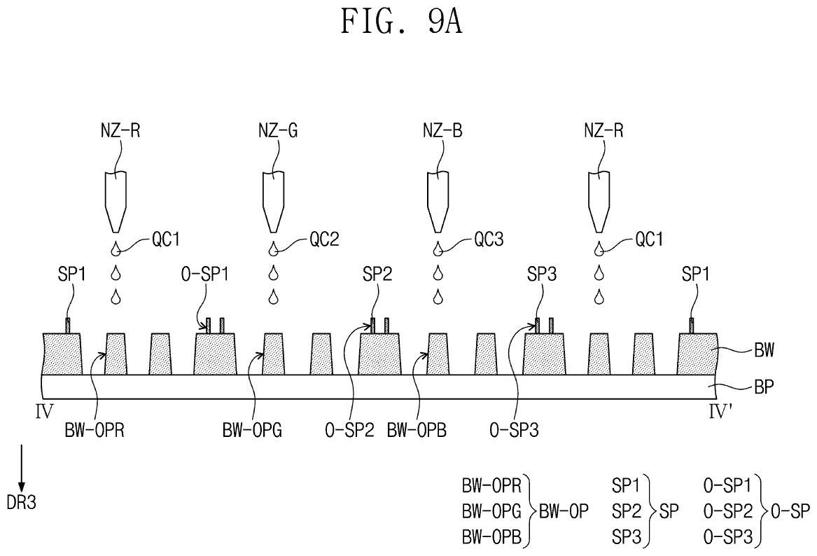

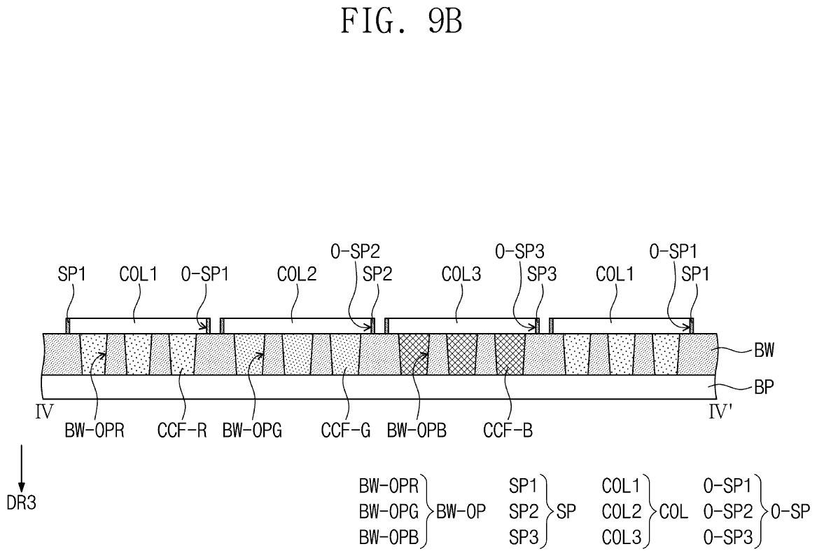

FIGS. 9A and 9B are schematic cross-sectional views showing some processes in the method for manufacturing a display device according to another embodiment of the disclosure. FIGS. 9A and 9B schematically show forming a barrier rib BW and light conversion patterns CCF-R, CCF-G, and CCF-B at a portion corresponding to the cross-section IV-IV′ of FIG. 5A. Hereinafter, in describing the method for manufacturing a display device according to an embodiment with reference to FIGS. 7, 9A, and 9B, the same reference numerals are given to components that are the same as the components described above, and detailed descriptions thereof will be omitted.

The method for manufacturing a display device shown in FIGS. 9A and 9B is different from the method for manufacturing a display device described with reference to FIGS. 8A to 8F in that the transmission pattern CCF-B corresponding to the third pixel region PXA-B and the first and second light conversion patterns CCF-R and CCF-G may be formed through a same inkjet process.

Referring to FIGS. 5A, 5B, 7, and 9A, in the patterning of a photoresist layer to form a division pattern (S400), a division pattern SP in which a division opening O-SP overlapping the first pixel region PXA-R, the second pixel region PXA-G, and the third pixel region PXA-B is defined may be formed. The division pattern SP shown in FIG. 9A may be formed using a mask in which the semi-transmission portion HTA overlapping the third pixel region PXA-B in the mask MK shown in FIG. 8C is replaced with the light blocking portion NTA. Accordingly, as shown in FIG. 9A, in the patterning of a photoresist layer, only the division pattern SP overlapping the peripheral region NPXA may be formed, and the transmission pattern CCF-B (FIG. 8C) may not be formed.

Thereafter, a first composition QC1 may be provided inside a (1-1)-th opening BW-OPR corresponding to the first pixel region PXA-R, a second composition QC2 may be provided inside a (1-2)-th opening BW-OPG corresponding to the second pixel region PXA-G, and a third composition QC3 may be provided inside a (1-3)-th opening BW-OPB corresponding to the third pixel region PXA-B. The first composition QC1 may include red quantum dots, the second composition QC2 may include green quantum dots, and the third composition QC3 may include a base resin and scatterers mixed with the base resin.

The division pattern SP may prevent the first to third compositions QC1, QC2, and QD3 from overflowing into adjacent pixel regions displaying different colors. The division pattern SP may prevent the first composition QC1 from overflowing into the adjacent (1-2)-th opening BW-OPG and (1-3)-th opening BW-OPB. The division pattern SP may prevent the second composition QC2 from overflowing into the adjacent (1-1)-th opening BW-OPR and (1-3)-th opening BW-OPB. The division pattern SP may prevent the third composition QC3 from overflowing into the adjacent (1-1)-th opening BW-OPR and (1-2)-th opening BW-OPG.

The first composition QC1, the second composition QC2, and the third composition QC3 may be provided using an inkjet process. An inkjet head may include a first nozzle group, a second nozzle group, and a third nozzle group. The first nozzle group includes multiple first nozzles NZ-R providing the first composition QC1. The second nozzle group includes multiple second nozzles NZ-G providing the second composition QC2. The third nozzle group includes multiple third nozzles NZ-B providing the third composition QC3.

Referring to FIGS. 5A, 5B, and 9A together, the first nozzle group, the second nozzle group, and the third nozzle group may provide the first to third compositions QC1, QC2, and QC3 to corresponding one of the first pixel region group PXG-R, the second pixel region group PXG-G, and the third pixel region group PXG-B, which are divided by the division pattern SP. The first nozzles NZ-R included in the first nozzle group may provide the first composition QC1 to each first pixel region group PXG-R divided by the division pattern SP. The second nozzles NZ-G included in the second nozzle group may provide the second composition QC2 to each second pixel region group PXG-G divided by the division pattern SP. The third nozzles NZ-B included in the third nozzle group may provide the third composition QC3 to each third pixel region group PXG-B divided by the division pattern SP. As the first pixel region PXA-R, the second pixel region PXA-G, and the third pixel region PXA-B are separated by the division pattern SP, the first composition QC1, the second composition QC2, and the third composition QC3 may not be mixed in an inkjet process.

According to an embodiment of the disclosure, the division pattern SP may surround the first pixel region group PXG-R including two or more first pixel regions PXA-R, and accordingly, the first composition QC1 may be concurrently provided in the (1-1)-th openings BW-OPR corresponding to two or more first pixel regions PXA-R. The division pattern SP may surround the second pixel region group PXG-G including two or more second pixel regions PXA-G, and accordingly, the second composition QC2 may be concurrently provided in the (1-2)-th openings BW-OPG corresponding to two or more second pixel regions PXA-G. The division pattern SP may surround the third pixel region group PXG-B including two or more third pixel regions PXA-B, and accordingly, the third composition QC3 may be concurrently provided in the (1-3)-th openings BW-OPB corresponding to two or more third pixel regions PXA-B. Accordingly, the inkjet process may be provided with reduced turn around time (TAT) to improve process efficiency.

Referring to FIGS. 5A, 5B, 9A, and 9B together, the first composition QC1, the second composition QC2, and the third composition QC3 provided to each of the (1-1)-th opening BW-OPR, the (1-2)-th opening BW-OPG, and the (1-3)-th opening BW-OPB may be cured. As a result, the first light conversion pattern CCF-R, the second light conversion pattern CCF-G, and the third light conversion pattern CCF-B may be formed.

The method for manufacturing a display device according to an embodiment may further include forming an organic pattern COL filling the division opening O-SP defined in the division pattern SP after the forming of the second light conversion pattern CCF-G and the third light conversion pattern CCF-B. A first organic pattern COL1 may be filled inside the first division opening O-SP1 overlapping the first pixel region PXA-R, a second organic pattern COL2 may be filled inside the second division opening O-SP2 overlapping the second pixel region PXA-G, and a third organic pattern COL3 may be filled inside the third division opening O-SP3 overlapping the third pixel region PXA-B.

According to an embodiment of the disclosure, a division pattern surrounding pixel regions displaying the same color on a barrier rib confining applied ink droplets for each pixel region is disposed, and accordingly, ink droplets may be effectively prevented from overflowing into pixel regions emitting light of different colors.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display panel including a first pixel region, a second pixel region, and a third pixel region each emitting source light;
a barrier rib disposed on the display panel and having first openings corresponding to each of the first pixel region, the second pixel region, and the third pixel region;
a first light conversion pattern disposed in a first-first opening among the first openings corresponding to the first pixel region and converting the source light into first color light;
a second light conversion pattern disposed in a first-second opening among the first openings corresponding to the second pixel region and converting the source light into second color light; and
a division pattern, at least a portion of the division pattern in contact with the barrier rib,
wherein the division pattern surrounds a corresponding one of the first pixel region, the second pixel region, and the third pixel region in a plan view.

2. The display device of claim 1, wherein
in the division pattern, a division opening overlapping a corresponding one of the first pixel region, the second pixel region, and the third pixel region in a plan view is defined, and
the display device further comprises an organic pattern disposed in the division opening.

3. The display device of claim 2, wherein in a plan view, an area of the division opening is greater than an area of each of the first openings.

4. The display device of claim 1, further comprising:
a transmission pattern disposed in a first-third opening among the first openings corresponding to the third pixel region and transmitting the source light,
wherein the transmission pattern and the division pattern include a same material.

5. The display device of claim 4, wherein a thickness deviation of the transmission pattern corresponding to the third pixel region is less than a thickness deviation of the first light conversion pattern corresponding to the first pixel region.

6. The display device of claim 1, wherein the division pattern comprises a base resin and scattering particles mixed with the base resin.

7. The display device of claim 1, wherein
the first pixel region comprises a plurality of first pixel regions,
the second pixel region comprises a plurality of second pixel regions,
the third pixel region comprises a plurality of third pixel regions, and
the display panel comprises:
a first pixel row including the plurality of first pixel regions and the plurality of third pixel regions, which are alternately arranged in a first direction; and
a second pixel row spaced apart from the first pixel row in a second direction intersecting the first direction, and including the plurality of second pixel regions arranged in the first direction.

8. The display device of claim 7, wherein
the first pixel row comprises a first pixel region group including n first pixel regions,
the second pixel row comprises a second pixel region group including m second pixel regions,
the division pattern comprises:
a first division pattern surrounding the first pixel region group in a plan view; and
a second division pattern surrounding the second pixel region group in a plan view, and
n and m are each independently an integer greater than or equal to 2.

9. The display device of claim 8, wherein
in the first division pattern, a first division opening overlapping the first pixel region and the third pixel region included in the first pixel region group is defined,
in the second division pattern, a second division opening overlapping the second pixel region included in the second pixel region group is defined, and
the display device further comprises:
a first organic pattern disposed in the first division opening; and
a second organic pattern disposed in the second division opening.

10. The display device of claim 1, wherein
the first pixel region comprises a plurality of first pixel regions,
the second pixel region comprises a plurality of second pixel regions,
the third pixel region comprises a plurality of third pixel regions, and
the display panel comprises:
a first pixel row including the plurality of first pixel regions arranged in a first direction; and
a second pixel row spaced apart from the first pixel row in a second direction intersecting the first direction, and including the plurality of second pixel regions arranged in the first direction.

11. The display device of claim 10, wherein
the first pixel row comprises a first pixel region group including n first pixel regions arranged in the first direction,
the second pixel row comprises a second pixel region group including m second pixel regions arranged in the first direction,
the division pattern surrounds each of the first pixel region group and the second pixel region group in a plan view, and
n and m are each independently an integer greater than or equal to 2.

12. The display device of claim 11, wherein
the display panel further comprises a third pixel row spaced apart from the first pixel row and the second pixel row in the second direction and including the third pixel regions arranged in the first direction,
the third pixel row comprises a third pixel region group including z third pixel regions arranged in the first direction,
the division pattern surrounds the third pixel region group in a plan view, and
is an integer greater than or equal to 2.

13. The display device of claim 1, further comprising:
a color filter layer disposed on the barrier rib,
wherein the color filter layer includes:
a first filter that transmits the first color light;
a second filter that transmits the second color light; and
a third color filter that transmits the source light.

14. The display device of claim 1, further comprising:
a base layer facing the display panel in a thickness direction of the display panel,
wherein the barrier rib is disposed on a lower surface of the base layer.

15. A display device comprising:
a display panel including a first pixel region, a second pixel region, and a third pixel region each emitting source light; and
a light conversion panel disposed to be spaced apart from the display panel in a thickness direction of the display panel,
wherein the light conversion panel includes:
a base layer;
a barrier rib disposed on a lower surface of the base layer and having first openings corresponding to the first pixel region, the second pixel region, and the third pixel region;
a first light conversion pattern disposed in a first-first opening among the first openings corresponding to the first pixel region and converting the source light into first color light;
a second light conversion pattern disposed in a first-second opening among the first openings corresponding to the second pixel region and converting the source light into second color light;
a transmission pattern disposed in a first-third opening among the first openings corresponding to the third pixel region and transmitting the source light; and
a division pattern disposed between the display panel and the barrier rib, and the transmission pattern and the division pattern include a same material.

16. A method for manufacturing a display device, the method comprising:
preparing a substrate on which a first pixel region and a second pixel region are defined;
forming a barrier rib including first openings corresponding to each of the first pixel region and the second pixel region;
forming a photoresist layer on the substrate and the barrier rib;
patterning the photoresist layer to form a division pattern having division openings overlapping each of the first pixel region and the second pixel region in a plan view; and
forming a light conversion pattern inside ones of the first openings corresponding to the first pixel region and the second pixel region.

17. The method of claim 16, wherein
a third pixel region adjacent to the first pixel region and the second pixel region is defined on the substrate,
the forming of the division pattern comprises patterning the photoresist layer, using a mask in which a transmission portion overlapping a portion of the barrier rib and a semi-transmission portion overlapping the third pixel region in a plan view are defined, and
in the forming of the division pattern, a transmission pattern is formed inside one of the first openings corresponding to the third pixel region.

18. The method of claim 16, wherein
a third pixel region adjacent to the first pixel region and the second pixel region is defined on the substrate, and
in the forming of the division pattern, a first division pattern surrounding the first pixel region and the third pixel region in a plan view, and a second division pattern surrounding the second pixel region in a plan view are formed.

19. The method of claim 16, wherein the forming of the light conversion pattern comprises providing a liquid quantum dot composition to the inside the ones of the first openings.

20. The method of claim 16, further comprising:
forming an organic pattern filling each of the division openings.
